(19) United States
(12) Patent Application Publication
(10) Pub. No.: US 2026/0082880 A1
(43) Pub. Date: Mar. 19, 2026

(54) BUILD UP BONDING LAYER PROCESS AND STRUCTURE FOR LOW TEMPERATURE BONDING

(71) Applicant: ADEIA SEMICONDUCTOR BONDING TECHNOLOGIES INC., San Jose, CA (US)

(72) Inventors: Gaius Gillman Fountain, Jr., Youngsville, NC (US); Pawel Mrozek, San Jose, CA (US); George Carlton Hudson, Wendell, NC (US)

(21) Appl. No.: 18/888,020

(22) Filed: Sep. 17, 2024

(51) Int. Cl. H10W 20/00; H10W 72/00; H10W 72/90; H10W 90/00

(52) U.S. Cl. CPC H10W 20/063; H10W 72/01951; H10W 72/942; H10W 72/952; H10W 90/792

(57) ABSTRACT

Disclosed herein are methods of forming a microelectronic component. In some embodiments, the methods include providing a substrate having a first surface, forming a first metal feature on the first surface, forming a second metal feature on the first metal feature, forming a dielectric layer over the substrate such that the dielectric layer directly contacts sidewalls of the first and second metal features, and planarizing the dielectric layer to form a second surface for hybrid bonding. After planarizing the dielectric layer, the second metal feature is exposed at the second surface.

### BACKGROUND

### Field

This application relates to direct bonding methods and structures, and more particularly to hybrid bonding methods and structures.

### Description of the Related Art

Microelectronic elements, such as integrated device dies or chips, may be mounted or stacked on other elements thereby forming a bonded structure. Direct bonding can be conducted at low temperatures and without external pressure. For example, hybrid bonding involves directly bonding non-conductive features (e.g., inorganic dielectrics) of different elements together, without intervening adhesives, while also directly bonding conductive features (e.g., metal pads) of the elements together. For example, a microelectronic element can be bonded to a carrier, such as a wafer, an interposer, a reconstituted wafer or other element. As another example, a microelectronic element can be bonded on top of another microelectronic element, for example a first integrated device die can be stacked on a second integrated device die. Each of the microelectronic elements can have conductive features, such as pads, for mechanically and electrically bonding the elements to one another. These conductive features are typically formed as part of a direct bonding layer formed on the surface of a metallization layer of the microelectronic elements. The metallization layers can include redistribution layers (RDLs) having conductive routing lines that extend in lateral directions and that connect conductive features of the microelectronic element to the conductive features of the direct bonding layer.

Due to its conductivity, copper is the most common metal in state-of-the-art integrated circuit fabrication. Copper has challenges, such as the difficulty of dry etching copper to produce reliable patterns. For this reason, copper is often patterned by damascene processing, involving the patterning of insulators with trenches, overfilling them with plated copper, and polishing them back to the trench confines.

Other difficulties presented by copper include its high diffusivity in common insulators, such that it can poison semiconductor devices, and its poor adhesion to common insulators, such as silicon oxide based materials. Accordingly, copper features are often lined with adhesion and barrier materials that promote adhesion between copper and the surrounding insulator and prevent copper atoms from the conductive pads from diffusing into the surrounding dielectric material during the process of forming the bonding layer. In a damascene process, the adhesion and barrier materials can be lined in the trench before copper fill. These processes and materials can increase the cost of metallization process and can complicate subsequent bonding by, for example, requiring higher annealing temperatures during bonding.

Accordingly, there is a continuing need for improved methods for forming bonded structures at lower costs.

### BRIEF DESCRIPTION OF THE DRAWINGS

FIG. 1A is a schematic side sectional view of two elements before being directly bonded, according to an embodiment.

FIG. 1B is a schematic side sectional view of the two elements of FIG. 1A after being directly bonded, according to an embodiment.

FIG. 2 is a flowchart illustrating a process of forming a redistribution level on a substrate, according to some embodiments, where the redistribution level includes a redistribution layer (RDL) and a via layer.

FIGS. 3A-3E are schematic side sectional views of microelectronic elements at various blocks of a process like that shown in FIG. 2.

FIG. 4 is a flowchart illustrating a process of forming a bonded structure, according to some embodiments.

FIG. 5 is a schematic side sectional view of a bonded structure formed according to a process like that shown in FIG. 4.

FIG. 6 is a flowchart illustrating a process for forming a microelectronic element that includes a multiple redistribution levels formed on a substrate, according to some embodiments.

FIGS. 7A and 7B are schematic side sectional view of a microelectronic element at various blocks of a process like that shown in FIG. 6.

FIG. 8 is a flowchart illustrating a process for forming a redistribution level on a substrate, according to some embodiments.

FIGS. 9A-9J are schematic side sectional views of microelectronic elements at various blocks of a process like that shown in FIG. 8.

FIG. 10 is a flowchart illustrating a process for forming a redistribution level on a substrate, according to some embodiments.

FIGS. 11A-11H are schematic side sectional views of microelectronic elements at various blocks of processes like those shown in FIG. 10.

FIG. 12 is a flowchart illustrating a process for forming a redistribution level on a substrate, according to some embodiments.

FIGS. 13A-13D are schematic side sectional views of microelectronic elements at various blocks of a process like that shown in FIG. 10.

### DETAILED DESCRIPTION

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 108a and/or 108b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Ser. No. 63/524,564 , filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

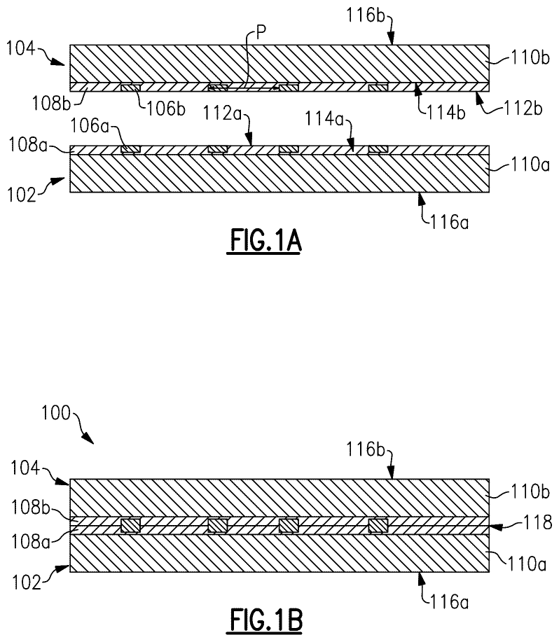

FIGS. 1A and 1B schematically illustrate cross-sectional side views of first and second elements 102, 104 prior to and after, respectively, a process for forming a directly bonded structure, and more particularly a hybrid bonded structure, according to some embodiments. In FIG. 1B, a bonded structure 100 comprises the first and second elements 102 and 104 that are directly bonded to one another at a bond interface 118 without an intervening adhesive. Conductive features 106a of a first element 102 may be electrically connected to corresponding conductive features 106b of a second element 104. In the illustrated hybrid bonded structure 100, the conductive features 106a are directly bonded to the corresponding conductive features 106b without intervening solder or conductive adhesive.

The conductive features 106a and 106b of the illustrated embodiment are embedded in, and can be considered part of, a first bonding layer 108a of the first element 102 and a second bonding layer 108b of the second element 104, respectively. Field regions of the bonding layers 108a, 108b extend between and partially or fully surround the conductive features 106a, 106b. The bonding layers 108a, 108b can comprise layers of non-conductive materials suitable for direct bonding, as described above, and the field regions are directly bonded to one another without an adhesive. The non-conductive bonding layers 108a, 108b can be disposed on respective front sides 114a, 114b of base substrate portions 110a, 110b.

The first and second elements 102, 104 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 102, 104, and back-end-of-line (BEOL) interconnect layers over such semiconductor portions. The bonding layers 108a, 108b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 110a, 110b, and can electrically communicate with at least some of the conductive features 106a, 106b. Active devices and/or circuitry can be disposed at or near the front sides 114a, 114b of the base substrate portions 110a, 110b, and/or at or near opposite backsides 116a, 116b of the base substrate portions 110a, 110b. In other embodiments, the base substrate portions 110a, 110b may not include active circuitry, but may instead comprise dummy substrates, passive interposers, passive optical elements (e.g., glass substrates, gratings, lenses), etc. The bonding layers 108a, 108b are shown as being provided on the front sides of the elements, but similar bonding layers can be additionally or alternatively provided on the back sides of the elements.

In some embodiments, the base substrate portions 110a, 110b can have significantly different coefficients of thermal expansion (CTEs), and bonding elements that include such different based substrate portions can form a heterogenous bonded structure. The CTE difference between the base substrate portions 110a and 110b, and particularly between bulk semiconductor (typically single crystal) portions of the base substrate portions 110a, 110b, can be greater than 5 ppm/° C. or greater than 10 ppm/° C. For example, the CTE difference between the base substrate portions 110a and 110b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 110a, 110b can comprise optoelectronic single crystal materials, including perovskite materials, that are useful for optical piezoelectric or pyroelectric applications, and the other of the base substrate portions 110a, 110b comprises a more conventional substrate material. For example, one of the base substrate portions 110a, 110b comprises lithium tantalate (LiTaO₃) or lithium niobate (LiNbO₃), and the other one of the base substrate portions 110a, 110b comprises silicon (Si), quartz, fused silica glass, sapphire, or a glass. In other embodiments, one of the base substrate portions 110a, 110b comprises a III-V single semiconductor material, such as gallium arsenide (GaAs) or gallium nitride (GaN), and the other one of the base substrate portions 110a, 110b can comprise a non-III-V semiconductor material, such as silicon (Si), or can comprise other materials with similar CTE, such as quartz, fused silica glass, sapphire, or a glass. In still other embodiments, one of the base substrate portions 110a, 110b comprises a semiconductor material and the other of the base substrate portions 110a, 110b comprises a packaging material, such as a glass, organic or ceramic substrate.

In some arrangements, the first element 102 can comprise a singulated element, such as a singulated integrated device die. In other arrangements, the first element 102 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 104 can comprise a singulated element, such as a singulated integrated device die. In other arrangements, the second element 104 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 102, 104 are shown, any suitable number of elements can be stacked in the bonded structure 100. For example, a third element (not shown) can be stacked on the second element 104, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 102. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 108a, 108b, the bonding layers 108a, 108b can be prepared for direct bonding. Non-conductive bonding surfaces 112a, 112b at the upper or exterior surfaces of the bonding layers 108a, 108b can be prepared for direct bonding by polishing, for example, by chemical mechanical polishing (CMP). The roughness of the polished bonding surfaces 112a, 112b can be less than 30 Å rms. For example, the roughness of the bonding surfaces 112a and 112b can be in a range of about 0.1 Å rms to 15 Å rms, 0.5 Å rms to 10 Å rms, or 1 Å rms to 5 Å rms. Polishing can also be tuned to leave the conductive features 106a, 106b recessed relative to the field regions of the bonding layers 108a, 108b.

Preparation for direct bonding can also include cleaning and exposing one or both of the bonding surfaces 112a, 112b to a plasma and/or etchants to activate at least one of the surfaces 112a, 112b. In some embodiments, one or both of the surfaces 112a, 112b can be terminated with a species after activation or during activation (e.g., during the plasma and/or etch processes). Without being limited by theory, in some embodiments, the activation process can be performed to break chemical bonds at the bonding surface(s) 112a, 112b, and the termination process can provide additional chemical species at the bonding surface(s) 112a, 112b that alters the chemical bond and/or improves the bonding energy during direct bonding. In some embodiments, the activation and termination are provided in the same step, e.g., a plasma to activate and terminate the surface(s) 112a, 112b. In other embodiments, one or both of the bonding surfaces 112a, 112b can be terminated in a separate treatment to provide the additional species for direct bonding. In various embodiments, the terminating species can comprise nitrogen. For example, in some embodiments, the bonding surface(s) 112a, 112b can be exposed to a nitrogen-containing plasma. Other terminating species can be suitable for improving bonding energy, depending upon the materials of the bonding surfaces 112a, 112b. Further, in some embodiments, the bonding surface(s) 112a, 112b can be exposed to fluorine. For example, there may be one or multiple fluorine concentration peaks at or near a bond interface 118 between the first and second elements 102, 104. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 100, the bond interface 118 between two non-conductive materials (e.g., the bonding layers 108a, 108b) can comprise a very smooth interface with higher nitrogen (or other terminating species) content and/or fluorine concentration peaks at the bond interface 118. In some embodiments, the nitrogen and/or fluorine concentration peaks may be detected using various types of inspection techniques, such as SIMS techniques. The polished bonding surfaces 112a and 112b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 108a and 108b can be directly bonded to one another without an adhesive. In some embodiments, the elements 102, 104 are brought together at room temperature, without the need for application of a voltage, and without the need for application of external pressure or force beyond that used to initiate contact between the two elements 102, 104. Contact alone can cause direct bonding between the non-conductive surfaces of the bonding layers 108a, 108b (e.g., covalent dielectric bonding). Subsequent annealing of the bonded structure 100 can cause the conductive features 106a, 106b to directly bond.

In some embodiments, prior to direct bonding, the conductive features 106a, 106b are recessed relative to the surrounding field regions, such that a total gap between opposing contacts after dielectric bonding and prior to anneal is less than 15 nm, or less than 10 nm. Because the recess depths for the conductive features 106a and 106b can vary across each element, due to process variation, the noted gap can represent a maximum or an average gap between corresponding conductive features 106a, 106b of two joined elements (prior to anneal). Upon annealing, the conductive features 106a and 106b can expand and contact one another to form a metal-to-metal direct bond.

During annealing, the conductive features 106a, 106b (e.g., metallic material) can expand while the direct bonds between surrounding non-conductive materials of the bonding layers 108a, 108b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials'melting temperature, such that bonds can form with lower anneal temperatures compared to soldering or thermocompression bonding.

In various embodiments, the conductive features 106a, 106b can comprise discrete pads, contacts, electrodes, or traces at least partially embedded in the non-conductive field regions of the bonding layers 108a, 108b. In some embodiments, the conductive features 106a, 106b can comprise exposed contact surfaces of TSVs (e.g., through silicon vias).

As noted above, in some embodiments, in the elements 102, 104 of FIG. 1A prior to direct bonding, portions of the respective conductive features 106a and 106b can be recessed below the non-conductive bonding surfaces 112a and 112b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 106a, 106b or to average depths of the recesses relative to local non-conductive field regions. Even for an individual conductive feature 106a, 106b, the vertical recess can vary across the feature, and so can be measured at or near the lateral middle or center of the cavity in which a given conductive feature 106a, 106b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 106a, 106b across the direct bond interface 118 (e.g., small or fine pitches for regular arrays).

In some embodiments, a pitch p of the conductive features 106a, 106b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 106a and 106b to one of the lateral dimensions (e.g., a diameter) of the bonding pad is less than is less than 20, or less than 10, or less than 5, or less than 3 and sometimes desirably less than 2. In various embodiments, the conductive features 106a and 106b and/or traces can comprise copper or copper alloys, although other metals may be suitable, such as nickel, aluminum, or alloys thereof. The conductive features disclosed herein, such as the conductive features 106a and 106b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 102, 104, as shown, the orientations of one or more conductive features 106a, 106b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 106b in the bonding layer 108b (and/or at least one internal conductive feature, such as a BEOL feature) of the upper element 104 may be tapered or narrowed upwardly, away from the bonding surface 112b. By way of contrast, at least one conductive feature 106a in the bonding layer 108a (and/or at least one internal conductive feature, such as a BEOL feature) of the lower element 102 may be tapered or narrowed downwardly, away from the bonding surface 112a. Similarly, any bonding layers (not shown) on the backsides 116a, 116b of the elements 102, 104 may taper or narrow away from the backsides, with an opposite taper orientation relative to front side conductive features 106a, 106b of the same element.

As described above, in an anneal phase of hybrid bonding, the conductive features 106a, 106b can expand and contact one another to form a metal-to-metal direct bond. In some embodiments, the materials of the conductive features 106a, 106b of opposite elements 102, 104 can interdiffuse during the annealing process. In some embodiments, metal grains grow into each other across the bond interface 118. In some embodiments, the metal is or includes copper, which can have grains oriented along the 111 crystal plane for improved copper diffusion across the bond interface 118. In some embodiments, the conductive features 106a and 106b may include nanotwinned copper grain structure, which can aid in merging the conductive features during anneal. There is substantially no gap between the non-conductive bonding layers 108a and 108b at or near the bonded conductive features 106a and 106b. In some embodiments, a barrier layer may be provided under and/or laterally surrounding the conductive features 106a and 106b (e.g., which may include copper). In other embodiments, however, such as those discussed hereinbelow, there may be no barrier and/or adhesion layer on side surfaces of the conductive features 106a and 106b to facilitate expansion during anneal.

As noted in the Background above, redistribution layers (RDLs) are typically formed using a damascene process. In damascene processes, a dielectric layer is formed and then patterned to form openings in the dielectric layer. An adhesion/barrier layer is deposited in the openings and then copper is deposited over the adhesion/barrier layer. The adhesion/barrier layer is designed to prevent the copper metal from diffusing into the dielectric material during the deposition process and also to improve adhesion between the sidewalls of the opening and the copper metal. In some arrangements, the adhesion/barrier layer can comprise titanium (Ti) or tantalum (Ta). For example, the adhesion/barrier layer can comprise Ti metal and/or TiN or Ta metal and/or TaN.

After depositing the copper metal, a CMP process is then performed to form a bonding surface suitable for hybrid bonding. In some cases, a multi-step CMP process is needed due to differences in removal rate for the different materials. For example, a first CMP process can be performed using a first slurry for bulk overburden removal. The first slurry is typically tuned to copper removal and to permit stopping on the barrier material. Once the barrier on the upper surface is exposed, a second CMP process is typically performed using a second slurry chemistry, where the second slurry chemistry tends to remove copper, barrier and surrounding insulator materials at roughly the same rate. In this second CMP process, the barrier layer and copper metal are polished until they are coplanar with (or recessed below) the non-conductive surface of the dielectric material. Having to use two different slurry chemistries (and two different polishing pads) increases the complexity and costs of performing hybrid bonding.

Accordingly, there is a continued need for improved hybrid bonding processes that do not require multi-step CMP process and two slurry chemistries (and two different polishing pads).

After forming the bonding surface, the element can be hybrid bonded to a second element having a hybrid bonding surface by bringing the bonding surfaces of the two elements together, which can cause direct bonding between the non-conductive surfaces of the hybrid bonding surfaces. As previously discussed, the conductive features of one or both of the elements can be recessed below the non-conductive surfaces such that, when the two hybrid bonding surfaces are initially brought together, the conductive features on the opposing elements are separated from each other by a gap. To cause the conductive features to contact each other, the elements can be annealed to cause the conductive features to expand and contact one another to form a metal-to-metal direct bond. The barrier/adhesion layer(s) between the dielectric material and the copper metal, noted above with respect to typical damascene copper features, can constrain the expansion of the copper metal because the copper metal can remain adhered to the surrounding insulator by way of the barrier/adhesion layer(s). To ensure that the copper features on the opposing the elements contact each other, the annealing temperature needs to be sufficiently high to allow the adhered copper to plastically deform and expand into contact with one another. However, annealing at too high of a temperature can degrade the performance of the bonded structure due to exceeding the thermal budget of the elements and/or the bonded structure.

Accordingly, there is a continued need for improved hybrid bonding processes that allow for annealing at lower temperatures.

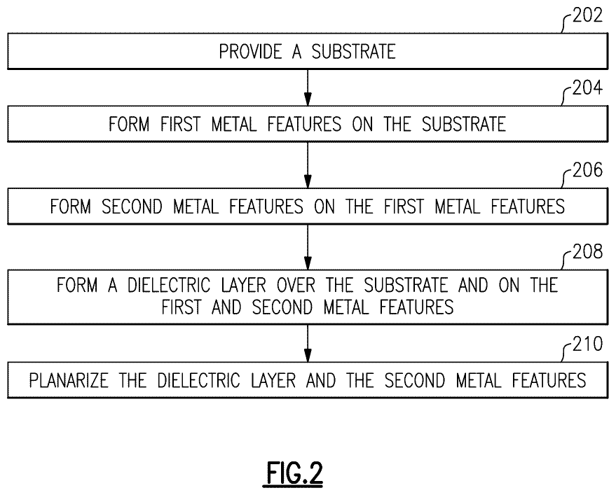

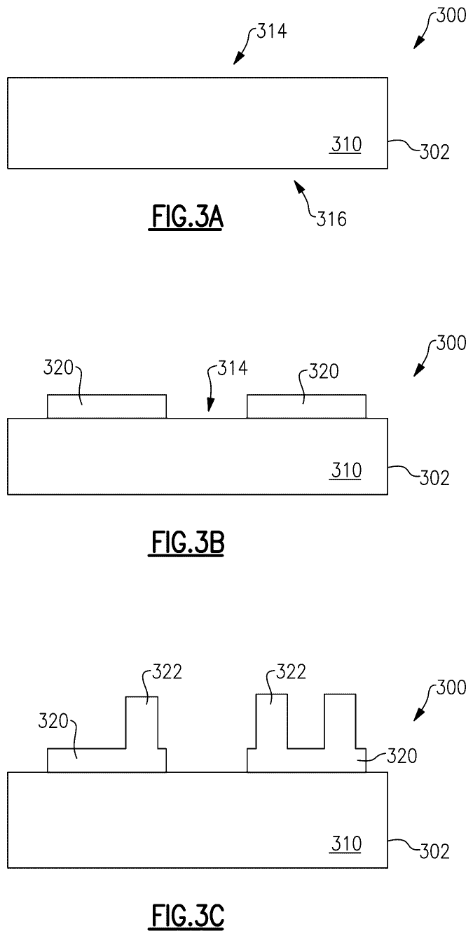

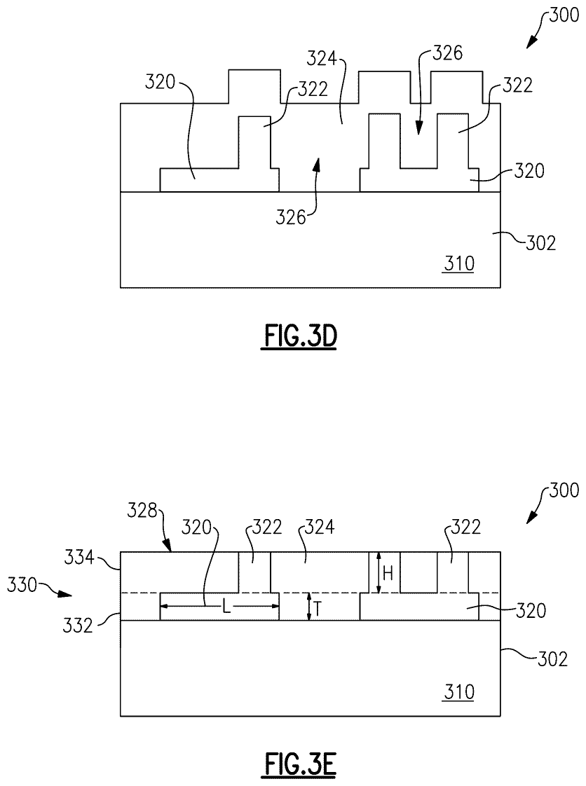

FIG. 2 is a flowchart illustrating a process 200 for forming a microelectronic component that includes forming a build-up redistribution level on an element, where the redistribution level includes a redistribution layer (RDL) and a via layer, where the RDL includes routing lines extending in a lateral direction and the via layer includes vias extending in a vertical direction. FIGS. 3A-3E are schematic side sectional views of a microelectronic element at various blocks of the process 200 shown in FIG. 2.

As shown in FIG. 3A, at block 202, a substrate 302 for an element 300 is provided. Substrate 302 may be similar or identical to the first element 102 discussed above in many respects. Accordingly, numerals used to identify features of the element 102 are incremented by 200 to identify certain similar features of the substrate 302. For example, as shown in FIG. 3A, the substrate 302 comprises a base substrate portion 310 having a front side 314 and an opposing back side 316. The base substrate portion 310, front side 314, and back side 316 can be similar or identical to base substrate portion 110a, 110b, front sides 114a, 114b, and back sides 116a, 116b. The substrate 302 can include any one or a combination of the features of the element 102.

In some embodiments, the substrate 302 comprises conductive features (e.g., active devices and/or circuitry, not shown) that can be patterned and/or otherwise disposed in or on the substrate 302. In some embodiments, the substrate 302 comprises a metallization layer (not shown) having a field dielectric and conductive features embedded in the field dielectric. In these embodiments, the conductive features can be disposed at or near the front side 314 and/or at or near back side 316 and, in some embodiments, can be exposed at a surface of the substrate (e.g., the surface at the front side 314 of the substrate 302 and/or the surface at the back side 316 of the substrate 302). In other embodiments, however, the substrate 302 may not include active circuitry, but may instead be a dummy substrate, a passive interposer, a passive optical element (e.g., glass substrates, gratings, lenses), a temporary carrier, etc. In some embodiments, the substrate 302 comprises an optoelectronic single crystal material, including a perovskite material (e.g., LiTaO₃ or LiNbO₃), which are useful for optical piezoelectric or pyroelectric applications. In other embodiments, the substrate 302 comprises a more conventional substrate material, such as silicon (Si), quartz, fused silica glass, sapphire, glass, or a single crystal compound semiconductor material (e.g., III-V materials, such as GaAs or GaN). In general, the substrate 302 can comprise a semiconductor substrate, a glass substrate, an organic substrate, or a ceramic substrate.

As shown in FIG. 3B, at block 204, first metal features 320 are formed on the substrate 302. The first metal features 320 comprise a conductive metal (e.g., copper, nickel, gold, and/or aluminum) and form routing lines that extend laterally along a surface of the substrate 302. In embodiments where conductive features are exposed at a surface of the substrate 302, the first metal features 320 can be formed on the substrate such that at least some of the first metal features 320 are formed on and electrically connected to the exposed conductive features. In the illustrated embodiment, the first metal features 320 are formed on the front side 314 of the substrate 302. In other embodiments, the first metal features 320 are formed on the back side 316.

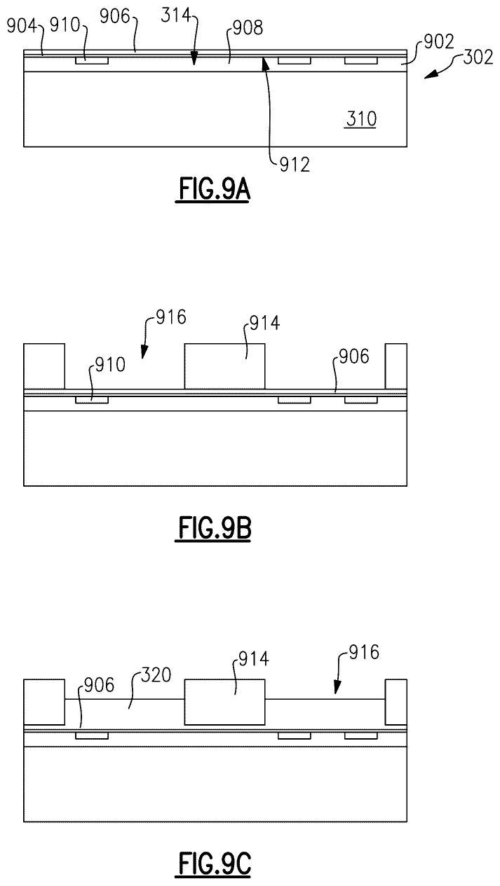

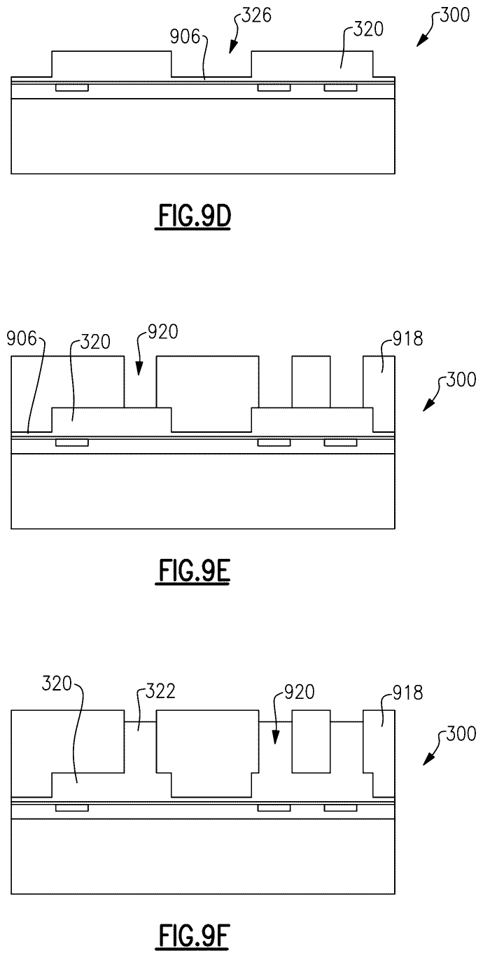

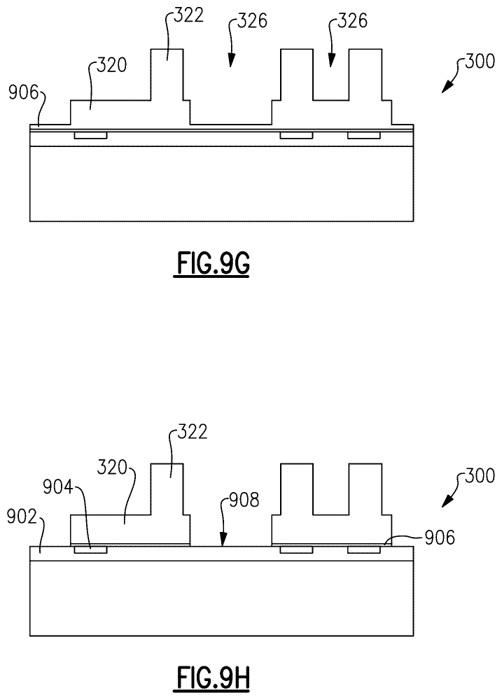

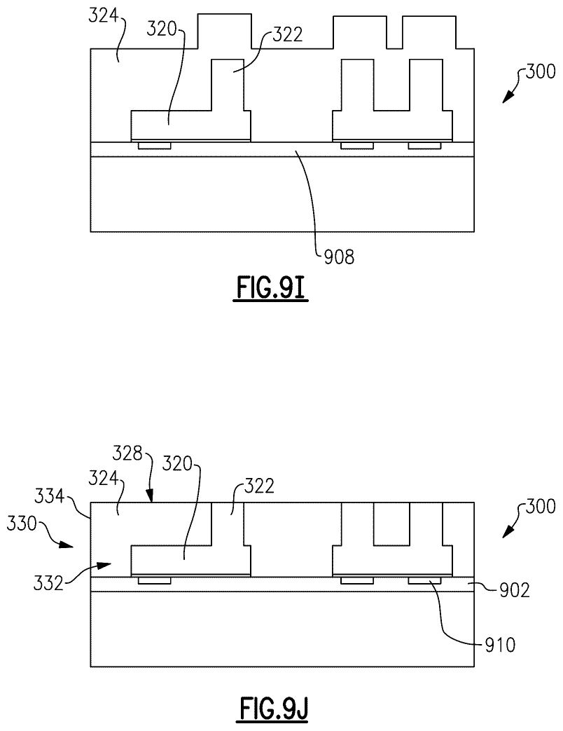

The first metal features 320 can be formed using any suitable process. For example, in some embodiments, such as the embodiment of FIGS. 9A-9D described below, the first metal features 320 are formed by depositing a barrier layer and seed layer over the substrate 302, forming a mask over the seed layer, patterning the mask to form openings in the mask and expose the seed layer, depositing the conductive metal into the openings over the seed layer, and then removing the mask to expose the seed layer.

As shown in FIG. 3C, at block 206, second metal features 322 are formed on the first metal features 320. The second metal features 322 comprise a conductive metal (e.g., copper, nickel, gold, and/or aluminum) and form vias that extend vertically, away from the substrate 302 and the first metal features 320. The second metal features 322 can be formed from the same conductive metal from which the first metal features 320 are formed, and can be formed directly on the first metal features 320 such that the second metal features 322 are electrically connected to the first metal features 320. In embodiments where the first metal features 320 are formed on and electrically connected to conductive features in the substrate 302, the second metal features 322 can be formed on the first metal features 320 such that one or more of the second metal features 322 are not vertically aligned with the conductive feature on which the first metal feature 320 is formed. In some embodiments, a single second metal feature 322 is formed on each first metal feature 320. In other embodiments, multiple second metal features 322 can be formed on one or more of the first metal features 320.

The second metal features 322 can be formed using any suitable process. For example, in some embodiments, such as the embodiment of FIG. 9E-9G described below, the second metal features 322 are formed by forming a mask over the seed layer and the first metal features 320, patterning the mask to form openings in the mask and the first metal features 320, depositing the conductive metal into the openings over the first metal features 320, and then removing the mask.

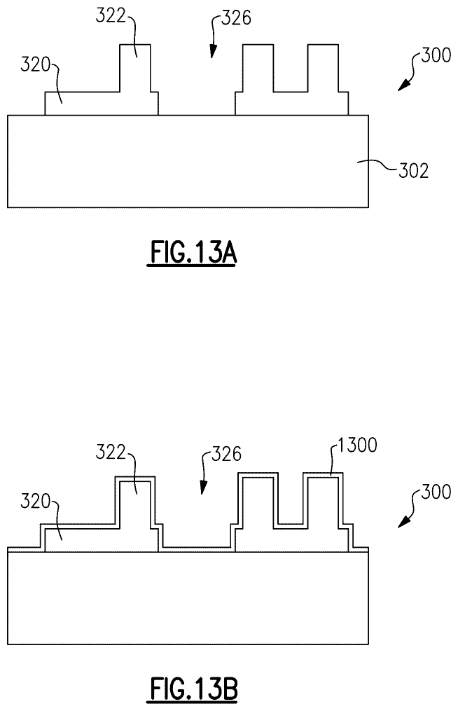

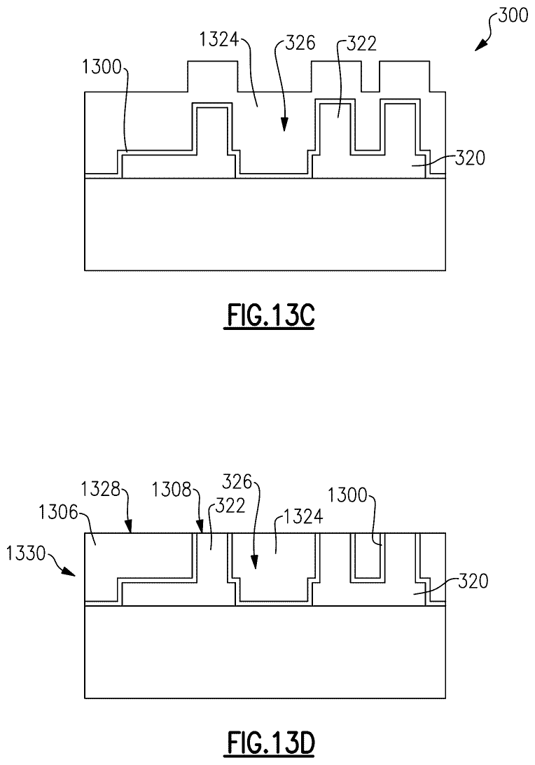

As shown in FIG. 3D, at block 208, a dielectric layer 324 is formed over the substrate 302 and the first and second metal features 320, 322. The dielectric layer 324 is formed such that it directly contacts the sidewalls of the first and second metal features 320, 322 and completely covers at least the first metal features 320. In some embodiments, the dielectric layer 324 also completely covers the second metal features 322. Adjacent first metal features 320 can be separated from each other by gaps 326 and, in some embodiments, the dielectric layer 324 completely fills the gaps 326. In some embodiments, the dielectric layer 324 comprises a single dielectric material. In other embodiments, the dielectric layer 324 comprises multiple dielectric materials layered together, such as in the embodiment of FIGS. 13A-13D described below. In some embodiments, the dielectric layer 324 comprises an inorganic dielectric material, such as a silicon oxide-based material. For example, in some embodiments, the dielectric layer 324 comprises silicon oxide (SiO₂), silicon oxynitride, silicon oxycarbide, or doped silicon oxide, such as F-doped SiO₂, borosilicate glass (BSG), or borophosphosilicate glass (BPSG), or combinations thereof. In other embodiments, however, the dielectric layer 324 comprises a different inorganic dielectric material, such as a silicon nitride-based material or a silicon carbide-based material.

Forming the dielectric layer 324 over the already-formed first and second metal features 320, 322 results in the dielectric material(s) of the dielectric layer 324 directly contacting the sidewalls of the first and second metal features 320, 322, which can allow for reduced annealing temperatures to be used in a subsequent annealing step. In some embodiments, the dielectric material(s) of the dielectric layer 324 can also react with the metal of the first and second metal features 320, 322 to form a metal-containing ceramic material on the sidewalls of the first and second metal features 320, 322, and this metal-containing ceramic material can weakly adhere to the dielectric material of the dielectric layer 324. For example, in embodiments where the first and second metal features comprise copper and the dielectric layer 324 comprises oxygen, such as a material including silicon and oxygen (e.g., a silicon oxide-based material), when the oxide material directly contacts the copper metal of the sidewalls of the first and second metal features 320, 322, the oxide material and the copper metal can react together, resulting in the formation of copper oxide (e.g., CuzO, CuO) on the sidewalls of the first and second metal features 320, 322. Copper, and even more so copper oxide, weakly adheres to the dielectric material that forms the dielectric layer 324, which means that the adhesion force between the dielectric material and the copper metal of the first and second metal features 320, 322 is reduced. In embodiments where the first and second metal features 320, 320 do not comprise copper and/or where the dielectric layer 324 does not include an oxide material, a similar effect can occur.

The lower adhesion allows for a lower annealing temperature (e.g., an annealing temperature less than 250° C.) to be used in a subsequent annealing step as part of hybrid bonding because the expansion of the copper metal is less constrained by adhesion between the metal of the metal features 320, 322 and the surrounding dielectric layer 324. Without barrier/adhesion layer(s), the metal can expand and slide with respect to the surrounding dielectric layer 324. Accordingly, forming the dielectric layer 324 such that the dielectric material directly contacts the sidewalls of the metal features 320, 322, without an intervening adhesion or barrier layers, can allow for low-temperature annealing for subsequent hybrid bonding, which means that any performance degradation of the element and/or bonded structure due to exceeding the thermal budget of the element and/or bonded structure can be reduced or even avoided.

As shown in FIG. 3E, at block 210, the dielectric layer 324 and the second metal features 322 are planarized to form a surface 328. In some embodiments, the degree of planarization is sufficient such that the surface 328 can serve as a bonding surface. In other embodiments, further metal layers can be formed over the structure of FIG. 3E. In some embodiments, planarizing the dielectric layer 324 comprises completely removing the portion of the dielectric layer 324 formed above the second metal features 322 to expose the second metal features 322. In some embodiments, planarizing the dielectric layer 324 also comprises removing some of the dielectric layer 324 that is formed in the gaps 326 between adjacent second metal features 322. In some embodiments, planarizing the second metal features 322 comprises removing at least some of the metal that forms the second metal features 322. In some embodiments, after planarizing the dielectric layer 324, the second metal features 322 can be recessed below the dielectric layer 324 at the bonding surface 328.

The dielectric layer 324 and the second metal features 322 can be planarized using any suitable planarization process. For example, in some embodiments, the planarization process comprises a CMP process that involves using a polishing pad and a slurry to polish the dielectric layer 324 and the second metal features 322 to form the surface 328. Additionally, unlike in conventional damascene processes where metal and typically copper overburden from the plating process needs to be removed from over a dielectric to form a flat surface, planarizing the dielectric layer 324 and the second metal feature 322 can be performed with a single polishing pad and a single slurry chemistry. Although no barrier is present in the illustrated embodiment, the slurry can be the same as those termed a “barrier slurry” in the industry, as it is tuned to remove oxides and metal at roughly the same rates, or to slightly recess metal. After performing the CMP process using the single polishing pad and the single slurry chemistry, the top surface of the second metal features 322 can be recessed below the top surface of the dielectric layer 324.

The dielectric layer 324, the first metal features 320, and the second metal features 322 form a redistribution level 330. The redistribution level 330 includes a redistribution layer (RDL) 332 and a via layer 334, where the RDL 332 includes the first metal features 320 and the lower portion of the dielectric layer 324 and the via layer 334 includes the second metal features 322 and the upper portion of the dielectric layer 324 and defines the surface 328 of the redistribution level 330. The first metal features 320 of the RDL 332 extend in a lateral direction that is generally parallel to the surface 328 while the second metal features 322 of the via layer 334 extend in a vertical direction that is generally perpendicular to the surface 328 and generally perpendicular to the lateral direction in in which the first metal features 320 extend in. In some embodiments, one or more of the first metal features 320 is a straight line having no curves, bends or corners. In other embodiments, one or more of the first metal features 320 has one or more curves, bends, or corners.

The first metal features 320 can have a length L, the RDL 332 can have a thickness T, and the second metal features can have a height H, where the length L represents the line (or path) length of the first metal features 320 and T+H is the total height of the redistribution level 330. In some embodiments, the length L is larger than the thickness T. For example, in some embodiments, the length L is at least 10 times larger than the thickness T. In other embodiments, however, the length L is larger than the thickness T by a different amount. For example, in some embodiments, the length L is at least 2 times larger than the thickness T, at least 5 times larger than the thickness T, at least 10 times larger than the thickness T, at least 20 times larger than the thickness T, at least 50 times larger than the thickness T, at least 100 times larger than thickness T, is 2-5 times larger than the thickness T, is 5-10 times larger than the thickness T, is 10-20 times larger than the thickness T, is 20-50 times larger than the thickness T, is 50-100 times larger than thickness T, or a value in a range that includes any of these values. Of course the RDL 332 typically includes multiple lines of different lengths.

After planarizing the dielectric layer 324 and the second metal features 322 and forming the redistribution level 330, the redistribution level 330 can be ready for additional processing. For example, in some embodiments, the surface 328 can be prepared (e.g., polished, activated and/or terminated) for hybrid bonding, and a second element can be directly bonded to the surface 328 of the redistribution level 330. In other embodiments, a second redistribution level can be formed on the surface 328.

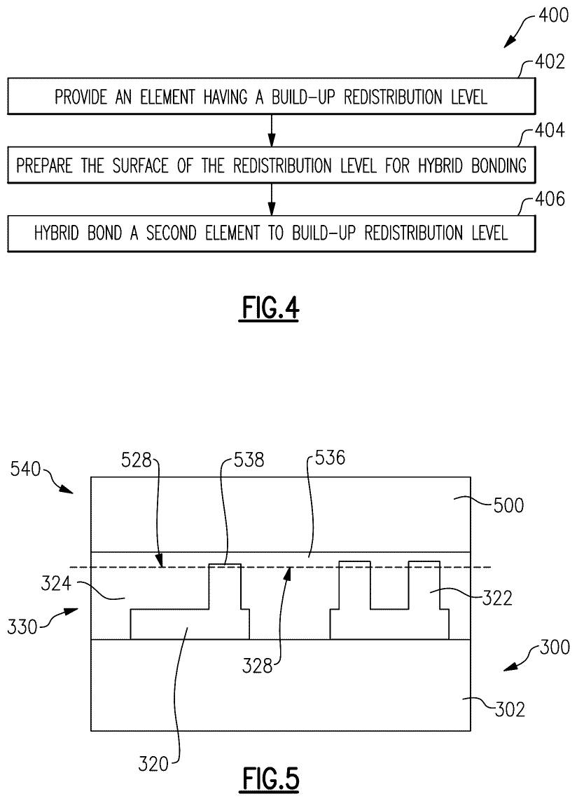

FIG. 4 is a flowchart illustrating a process 400 for forming a bonded structure that includes bonding an element having a build-up redistribution level to another element. FIG. 5 is a schematic side sectional view of a bonded structure formed according to the process 400 shown in FIG. 4.

At block 402, element 300 having build-up redistribution level 330 is provided. For example, as described above in connection with FIGS. 2 and 3A-3E, the redistribution level 330 can be formed using a build-up process whereby the first and second metal features 320, 322 are formed on the substrate 302 before the dielectric layer 324 is formed over the first and second metal features 320, 322. The dielectric layer 324 and second metal features 322 are then planarized to form the surface 328. The surface 328 is sufficiently planarized to form a hybrid bonding surface that includes a dielectric field region 336 and bond pads 338, where the dielectric field region 336 is formed by the dielectric layer 324 and the bond pads 338 are formed from the second metal features 322. In some embodiments, the bond pads 338 are recessed below the dielectric field region 336.

At block 404, the surface 328 is prepared for hybrid bonding. In some embodiments, preparing the surface 328 for hybrid bonding comprises polishing the surface 328 to a high degree, as described above. In some embodiments, preparing the surface 328 comprises activating the surface 328. In some embodiments, activating the surface 328 comprises plasma activating the surface 328 by exposing the surface 328 to one or plasmas, such as a nitrogen plasma and/or an oxygen plasma, or by slight etching. In some embodiments, the activation or other process can result in terminating species, such as nitrogen, that can increase bonding strength. In some embodiments, activating the surface 328 comprises chemically activating the dielectric field region 336 of the bonding surface. In some embodiments, preparing the surface 328 for hybrid bonding comprises rinsing the surface 328 to remove any particulate matter on the surface 328, and then drying the surface 328. Activation can sometimes be omitted, particularly if the other surface to be hybrid bonded to the surface 328 is activated. Termination can also be provided separately from or without plasma activation, such by ammonium dip.

As shown in FIG. 5, at block 406, a second element 500 is hybrid bonded to the prepared surface 328 of the redistribution level 330 to form a bonded structure 540. The second element 500 comprises a bonding surface 528, a dielectric field region 536, and conductive features 538, where the bonding surface 528 includes the conductive features 538 and the dielectric field region 536. The bonding surface 528 can be activated and/or terminated and prepared for hybrid bonding with element 300. In some embodiments, both the bonding surface 528 of the second element 500 and the surface 328 of the element 300 are activated and/or terminated. In some embodiments only one of the two bonding surfaces 328, 528 is activated and/or terminated, while both bonding surfaces 328, 528 are sufficiently planarized for hybrid bonding. The conductive features 538 comprise a conductive metal. For example, in some embodiments, the conductive metal comprises copper, aluminum, tin, nickel, gold, or an alloy of one or more of these elements. In some embodiments, the dielectric field region 536 comprises an inorganic dielectric material, such as silicon oxide, silicon nitride, silicon oxynitride, and can include carbon, such as silicon carbide, silicon oxycarbonitride, low K dielectric materials, SiCOH dielectrics, silicon carbonitride, diamond-like carbon, a material comprising a diamond surface, or combinations thereof. In some embodiments, the dielectric field region 536 comprises the same dielectric material as the dielectric layer 324; in other embodiments the bonding dielectrics of the two substrates are different.

In some embodiments, the second element 500 can have a structure that is generally similar to the structure of element 300, which can also be referred to as the first element 300. For example, the second element 500 can include a redistribution level formed on a substrate, where the redistribution level is formed using a build-up process whereby first and second metal features are formed on the substrate before a dielectric layer is formed over the first and second metal features. The dielectric layer and second metal features are then planarized to form the bonding surface 328, which includes the dielectric field region 536 and the conductive features 538. In some embodiments, the conductive features 538 comprise copper metal, the dielectric field region 536 comprises an oxide material, and the second element 500 does not include an adhesion and/or barrier layer between the sidewalls of the conductive features 538 and the oxide material of the dielectric field region 536. Additionally, copper oxide can be formed between the sidewalls of the conductive features 538 and the dielectric field region 536. The lack of adhesion and/or barrier materials, and/or presence of copper oxide at the sidewalls, can result in reduced adhesion between the conductive features 538 and the dielectric field region 536. In some embodiments, one or more of the conductive features 538 is recessed below the bonding surface 528. In other embodiments, the conductive features 538 are generally coplanar with the dielectric field region 536 or protrude above the dielectric field region 536 prior to bonding. In general, the second element 500 can have any structure that is suitable for hybrid bonding with the element 300, including conventional damascene conductive features with adhesion and/or barrier materials at the sidewalls.

The second element 500 is hybrid bonded to the redistribution level 330 of the element 300 by contacting the bonding surface 528 of the second element to the surface 328 so that the dielectric field region 336 of the bonding surface 328 and the dielectric field region 536 of the bonding surface 528 contact each other, which can cause chemical bonds (e.g., covalent bonds) to occur spontaneously between the dielectric material of the dielectric field region 336 and the dielectric material of the dielectric field region 536, even at room temperature and without external pressure beyond initiating contact. In some embodiments, hybrid bonding the second element 500 to the redistribution level 330 includes annealing the bonded structure 540 to cause the bond pads 338 to contact the conductive features 538. In some embodiments, annealing the bonded structure 540 causes one or both of the second metal features 322 and the conductive features 538 to expand and contact each other, resulting in the materials of the bond pads 338 inter-diffusing with the materials of the opposing conductive features 538. In some embodiments, one or more of the conductive features 538 and a corresponding one of the second metal features 522 can be misaligned with each other such that a portion of the conductive feature 538 and/or corresponding second metal features 322 overlaps with and contacts the dielectric portion of the opposing surface (e.g., a conductive feature 538 overlaps with the dielectric field region 336 and/or a second metal feature 322 overlaps with the dielectric field region 536). In some embodiments, the first metal features 320 also expand during the annealing process. In some embodiments, annealing the bonded structure 540 can also increase the strength of the chemical bonds between the dielectric field region 336 and the dielectric field region 536. In some embodiments, due at least in part to the reduced adhesion between the sidewalls of the first and second metal features 320, 322 and the dielectric layer 324, annealing the bonded structure 540 can be performed at a temperature of 250° C. or less. In other embodiments, however, the bonded structure 540 can be annealed at a different temperature. For example, in some embodiments, the bonded structure 540 can be annealed at a temperature of 300° C. or less, 250° C. or less, 200° C. or less, 150° C. or less, 100° C. or less, a temperature between 50° C. and 300° C., a temperature between 100° C., and 250° C., a temperature between 150° C. and 200° C., or a temperature in a range defined by any of the values.

After hybrid bonding the second element 500 to the redistribution level 330, the bonded structure 540 can undergo additional processing. For example, in some embodiments, the bonded structure 540 can be singulated to form one or more singulated bonded structures and/or can be bonded to one or more other elements (e.g., dies, substrates, wafers, etc.). In some embodiments, the additional processing can include thinning the bonded structure 540 (either before or after being singulated and/or bonded to another element or after). For example, in some embodiments, the backsides of one or both of elements 300, 500 (e.g., the sides of the elements 300, 500 opposite from the bonding surfaces 328, 528) can be thinned. In some embodiments, after thinning, the backsides of one or both of the elements 300, 500 can be etched to reveal TSVs or other metallization structures within the elements 300, 500. In some embodiments, the additional processing can include processing the backside of one or both of the elements 300, 500 to form one or more bonding surfaces. In some embodiments, a conductive barrier layer can be formed between one or more of the exposed metallization structures of the substrate 302 and the deposited conductive layer that forms the first conductive features 320. In some embodiments, one or more other elements (e.g., dies, substrates, wafers, etc.) can be bonded to the backside (e.g., to the bonding surface or the conductive layer) of one or both of the elements 300, 500. In some embodiments (e.g., embodiments where the substrate 302 comprises a dummy substrate or a temporary carrier), the substrate 302 can be removed from the redistribution level 330 after hybrid bonding the element 300 to the second element 500, such that the redistribution level 330 serves as a hybrid bonded transfer RDL.

In the embodiment shown in FIGS. 4 and 5, after forming the redistribution level 330, a second element 500 is hybrid bonded to the surface 328 of the redistribution level 330. In other embodiments, however, a second redistribution level can be formed on the surface 328 after forming the redistribution level 330 and before bonding.

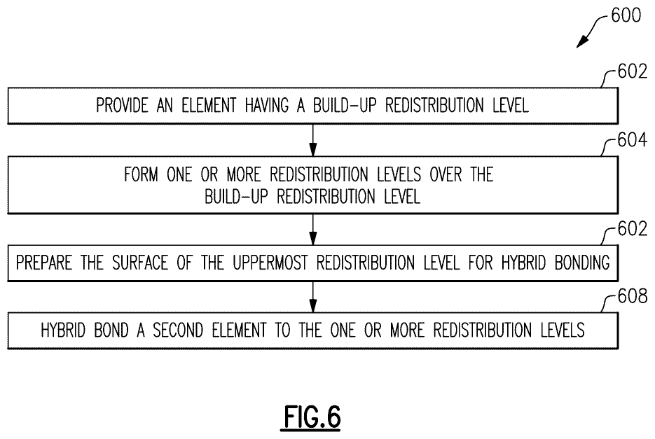

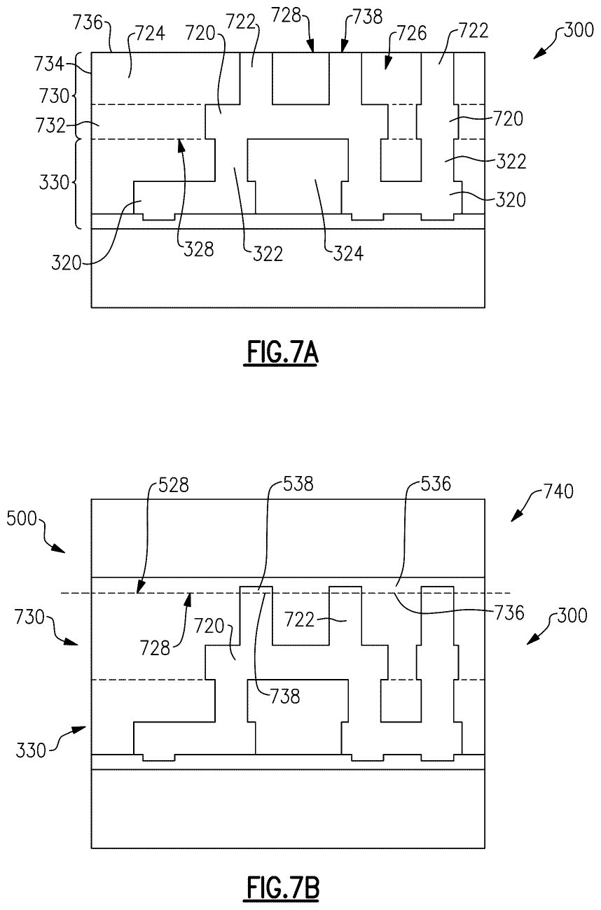

FIG. 6 is a flowchart illustrating a process 600 for forming a microelectronic component that includes forming a build-up redistribution level on a surface of another build-up redistribution level. FIGS. 7A and 7B are schematic side sectional views of a microelectronic element at various blocks of the process 600 shown in FIG. 6.

At block 602, element 300 having build-up redistribution level 330 is provided. As described above in connection with FIGS. 2 and 3A-3E, the redistribution level 330 is formed using a build-up process whereby the first and second metal features 320, 322 are formed on the substrate 302 before the dielectric layer 324 is formed over the first and second metal features 320, 322. The dielectric layer 324 and second metal features 322 are then planarized to form the surface 328.

As shown in FIG. 7A, at block 604, a second redistribution level 730 is formed on the redistribution level 330. In some embodiments, the second redistribution level 730 is formed using the same or similar build-up process used to form the redistribution level 330 on the substrate 302. Specifically, the second redistribution level 730 is formed using a build-up process that includes forming first metal features 720 on the surface 328. The first metal features 720 comprise a conductive metal and form routing lines that extend laterally along the surface 328. The first metal features 720 can be formed on the redistribution level 330 such that at least a portion of each of the first metal features 720 is formed on and electrically connected to the second metal features 322. In some embodiments, one or more of the first metal features 720 is electrically cofeannected to a single second metal feature 322. In other embodiments, including the embodiment shown in FIG. 7A, one or more of the first features 720 is formed on and electrically connected to multiple second metal features 322.

After forming the first metal features 720, second metal features 722 are formed on the first metal features 720 by a similar build-up process such that they are formed/patterned prior to filling their gaps with dielectric. The second metal features 722 comprise a conductive metal and form vias that extend vertically, away from the redistribution level 330 and the first metal features 720. The second metal features 722 can be formed from the same conductive metal that the first metal features 720 are formed from and can be formed directly on the first metal features 720 such that each of the second metal features 722 are electrically connected to at least one of the first metal features 720. The second metal features 722 can be formed on the first metal features 720 such that at least some of the second metal features 722 are not vertically aligned with at least one of the second conductive features 320 on which the corresponding first metal features 720 are formed. In some embodiments, a single second metal feature 722 is formed on each first metal features 720. In other embodiments, multiple second metal features 722 can be formed on one more of the first metal features 720. The second metal features 722 can be formed using any suitable process. For example, in some embodiments, the second metal features 722 are formed by forming a mask over the redistribution level 330 and the first metal features 720, patterning the mask to form openings in the mask and the first metal features 720, depositing the conductive metal into the openings over the first metal features 720, and then removing the mask.

After forming the second metal features 722, a dielectric layer 724 is formed over the redistribution level 330 and the first and second metal features 720, 722. The dielectric layer 724 is formed such that it directly contacts the sidewalls of the first and second metal features 720, 722 and covers at least the first metal features 720. In some embodiments, the dielectric layer 724 also covers the second metal features 722. Adjacent first metal features 720 can be separated from each other by gaps 726 and, in some embodiments, the dielectric layer 724 completely fills the gaps 726. In some embodiments, the dielectric layer 724 comprises a single dielectric material. In other embodiments, the dielectric layer 724 comprises multiple dielectric materials layered together. In some embodiments, the dielectric layer 724 comprises the same dielectric material(s) that the dielectric layer 324 comprises. In some embodiments, the dielectric layer 724 comprises an inorganic dielectric material, such as a silicon oxide-based material. For example, in some embodiments, the dielectric layer 724 comprises silicon oxide (SiO₂), silicon oxynitride, silicon oxycarbide, or doped silicon oxide, such as F-doped SiO₂, borosilicate glass (BSG), or borophosphosilicate glass (BPSG). In other embodiments, however, the dielectric layer 724 comprises a different inorganic dielectric material, such as a silicon nitride-based material.

As discussed above in connection with FIG. 3D, forming the dielectric layer 724 over the already-formed first and second metal features 720, 722 results in the dielectric material(s) of the dielectric layer 724 directly contacting the sidewalls of the first and second metal features 720, 722, which can allow for reduced annealing temperatures to be used in a subsequent annealing step due to the dielectric material weakly adhering to the already-formed first and second metal features 720, 722, without any intervening adhesion and/or barrier layers.

After forming the dielectric layer 724 over the first and second metal features 720, 722, the dielectric layer 724 and the second metal features 722 are planarized to form a surface 728. In some embodiments, planarizing the dielectric layer 724 comprises completely removing the portion of the dielectric layer 724 formed above the second metal features 722 to expose the second metal features 722. In some embodiments, planarizing the dielectric layer 724 also comprises removing some of the dielectric layer 724 that is formed in the gaps 726 between adjacent second metal features 722. In some embodiments, planarizing the second metal features 722 comprises removing at least some of the metal that forms the second metal features 722. In some embodiments, the surface 728 is sufficiently planarized to serve as a hybrid bonding surface that includes a dielectric field region 736 and bond pads 738, where the dielectric field region 736 is formed by the dielectric layer 724 and the bond pads 738 are formed from the second metal features 722. In some embodiments, the bond pads 738 are recessed below the dielectric field region 736.

The dielectric layer 724 and the second metal features 722 can be planarized using any suitable planarization process. For example, in some embodiments, the planarization process comprises a CMP process that involves using a polishing pad and a slurry to polish the dielectric layer 724 and the second metal features 722 to form the surface 728. Additionally, unlike in conventional damascene processes where metal overburden from the plating process needs to be removed to form a flat surface, planarizing the dielectric layer 724 and the second metal feature 722 can be performed with a single polishing pad and a single slurry chemistry. Although no barrier is present in the illustrated embodiment, the slurry can be the same as those termed a “barrier slurry” in the industry, as it is tuned to remove oxides and metal at roughly the same rates, or to slightly recess metal. After performing the CMP process using the single polishing pad and the single slurry chemistry, the top surface of the second metal features 722 can be recessed below the top surface of the dielectric layer 724.

The dielectric layer 724, the first metal features 720, and the second metal features 722 form a second redistribution level 730. The second redistribution level 730 includes a second redistribution layer (RDL) 732 and a second via layer 734. The second RDL 732 is formed on the surface 328 and includes the first metal features 720 and the lower portion of the dielectric layer 724. The second via layer 734 is formed on the second RDL 732 and includes the second metal features 722 and the upper portion of the dielectric layer 724 and defines the surface 728 of the second redistribution level 730. The first metal features 720 of the second RDL 732 extend in a lateral direction that is generally parallel to the surface 728 and to the lateral direction in which the first metal features 320 of the RDL 332 extend, while the second metal features 722 of the second via layer 734 extend in a vertical direction that is generally perpendicular to the surface 728 and to the lateral direction in in which the first metal features 720 extend in but that is generally parallel to the vertical direction in which the second metal features 322 of the via layer 334 extend. In some embodiments, one or more of the first metal features 720 is a straight line having no curves, bends or corners. In other embodiments, one or more of the first metal features 720 has one or more curves, bends, or corners. The first metal features 720 can have a length that is greater than a thickness of the second RDL 732.

At block 606, the surface 728 is prepared for hybrid bonding. In some embodiments, preparing the surface 728 for hybrid bonding comprises polishing the surface 728 to a high degree, as described above. In some embodiments, preparing the surface 728 comprises activating the surface 728, such as plasma activating the surface 728 and/or chemically activating the dielectric field region 736 of the bonding surface. In some embodiments, preparing the surface 728 for hybrid bonding comprises rinsing the surface 728 to remove any particulate matter on the surface 728, and then drying the surface 728. Activation can sometimes be omitted, particularly if the other surface to be hybrid bonded to the surface 728 is activated. Termination can also be provided separately from or without plasma activation, such by ammonium dip.

As shown in FIG. 7B, at block 608, second element 500 is hybrid bonded to the prepared bonding surface 728 of the second redistribution level 730 to form a bonded structure 740. The second element 500 is hybrid bonded to the second redistribution level 730 by contacting the bonding surface 528 to the prepared surface 728 so that the dielectric field region 736 and the dielectric field region 536 contact each other, which can cause chemical bonds (e.g., covalent bonds) to occur spontaneously between the dielectric material of the dielectric field region 736 and the dielectric material of the dielectric field region 536, even at room temperature and without external pressure beyond initiating contact. The bonding surface 528 can be activated and/or terminated and prepared for hybrid bonding with element 300. In some embodiments, both the bonding surface 528 of the second element 500 and the surface 728 of the element 300 are activated and/or terminated. In some embodiments only one of the two bonding surfaces 328, 728 is activated and/or terminated, while both bonding surfaces 328, 728 are sufficiently planarized for hybrid bonding. In some embodiments, hybrid bonding the second element 500 to the redistribution level 730 includes annealing the bonded structure 740 to cause the bond pads 738 to contact the conductive features 538. In some embodiments, annealing the bonded structure 740 causes one or both of the second metal features 722 and the conductive features 538 to expand and contact each other, resulting in the materials of the bond pads 738 inter-diffusing with the materials of the opposing conductive features 538. In some embodiments, one or more of the first metal features 320, the second metal features 322, and the first metal features 720 also expands during the annealing process. In some embodiments, annealing the bonded structure 740 can also increase the strength of the chemical bonds between the dielectric field region 736 and the dielectric field region 536. In some embodiments, due at least in part to the reduced adhesion between the sidewalls of the first and second metal features 720, 722 and the dielectric layer 724, annealing the bonded structure 740 can be performed at a temperature of 250° C. or less. In other embodiments, however, the bonded structure 740 can be annealed at a different temperature. For example, in some embodiments, the bonded structure 740 can be annealed at a temperature of 300° C. or less, 250° C. or less, 200° C. or less, 150° C. or less, 100° C. or less, a temperature between 50° C. and 300° C., a temperature between 100° C., and 250° C., a temperature between 150° C. and 200° C., or a temperature in a range defined by any of the values.

After hybrid bonding the second element 500 to the second redistribution level 730, the bonded structure 740 can undergo additional processing, such as singulating the bonded structure 740, thinning the bonded structure 740 (either before or after being singulated and/or bonded to another element or after), etching the backsides of one or both of the elements 300, 500, and/or bonding one or more other elements (e.g., dies, substrates, wafers, etc.) to the backside(s) of one or both of the elements 300, 500. In some embodiments (e.g., embodiments where the substrate 302 comprises a dummy substrate or a temporary carrier), the substrate 302 can be removed from the redistribution levels 730, 330 after hybrid bonding the element 300 to the second element 500, such that the redistribution levels 730, 330 serve as hybrid bonded transfer RDL.

In the illustrated embodiment, after forming the second redistribution level 730, the second element 500 is hybrid bonded to the second redistribution level 730. In other elements, however, one or more additional redistribution levels can be formed on the second redistribution level 730 and the second element 500 can be hybrid bonded to the one or more other redistribution levels.

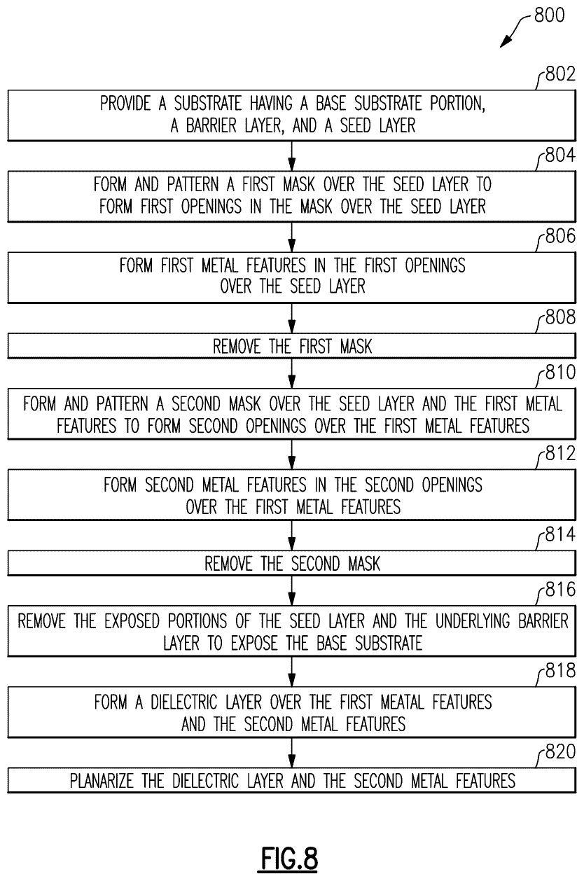

FIG. 8 is a flowchart illustrating more detailed process 800 for forming the build-up redistribution level 330 on the element 300. FIGS. 9A-9J are schematic side sectional views of the element 300 and redistribution level 330 at various blocks of the process 800 shown in FIG. 8.

As shown in FIG. 9A, at block 802, a substrate 302 is provided. The substrate 302 includes the base substrate portion 310, a metallization layer 902, a barrier layer 904, and a seed layer 906. The metallization layer 902 includes a field dielectric 908 and conductive features 910 formed in the field dielectric 908.

The metallization layer 902 is formed on the front side 314 of the base substrate portion 310 and has a surface 912 that is defined by the field dielectric 908 and the conductive features 910. In some embodiments, the field dielectric 908 comprises an inorganic dielectric, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. In some embodiments, the conductive features 910 comprise a conductive metal, such as copper, aluminum, or alloys thereof. In some embodiments, conductive features 910 are electrically connected to active devices, conductive vias, routing lines, or other conductive elements within the base substrate portion 310. In some embodiments, the metallization layer 902 can be the uppermost or last metallization layer of a plurality of BEOL metallization layers on the front side 314 of the base substrate portion 310. Accordingly, the metallization layer 902 can be formed at a chip foundry, for example, using process nodes typical for BEOL at the foundry, as opposed to a packaging facility.

The barrier layer 904 is formed over the surface 912 of the metallization layer 902. In some embodiments, the barrier layer 904 comprises a conductive barrier material, such as a barrier metal, barrier alloy, or barrier metal nitride. For example, in some embodiments, the barrier layer 904 comprises one or more of titanium metal, titanium nitride, tantalum metal, tantalum nitride, ruthenium, tungsten, titanium-tungsten alloy, etc. The barrier layer 904 is formed by depositing the conductive barrier material over the surface 912 of metallization layer 902 such that the conductive barrier material covers the surface 912. In some embodiments, including the illustrated embodiment, the barrier layer 904 completely covers the surface 912. In other embodiments, the barrier layer 904 only partially covers the surface 912. For example, in some embodiments, the barrier layer 904 covers the field dielectric 908 without covering one or more of the conductive features 910.

The seed layer 906 is formed over the barrier layer 904. In some embodiments, the seed layer 906 comprises a conductive metal. For example, in some embodiments, the seed layer 906 comprises copper, aluminum, nickel, and/or gold. The seed layer 906 is formed by blanket depositing the conductive metal over the barrier layer 904. In some embodiments, including the illustrated embodiment, the seed layer 906 completely covers the barrier layer 904. In other embodiments, however, the seed layer 906 only partially covers the barrier layer 904. For example, in some embodiments, the seed layer 906 is formed over the conductive features 910 without being formed over at least a portion of the field dielectric 908.

As shown in FIG. 9B, at block 804, a first mask 914 is formed over the seed layer 906 and patterned to form first openings 916 in the first mask 914. The first mask 914 can be formed from any suitable material, such as resist, and can be patterned using any suitable patterning technique. For example, in some embodiments, the first mask 914 can be patterned by selectively irradiating and developing a photoresist layer, or a patterned resist can have its pattern extended down into a hard mask material. The first openings 916 can extend through the first mask 914 and can be formed over the conductive features 910 such that the portions of the seed layer 906 formed over the conductive features 910 are exposed through the first openings 916. The size and shape of the individual openings 916 correspond to the planned size and shape of the corresponding first metal features (e.g., first metal features 320) that are to be formed in each of the first openings 916. The first openings 916 can have a straight profile, a V-shaped profile, or any other suitable profile and, in some embodiments, the profile can depend on the process used to pattern the first openings 916 in the first mask 914 and/or the material from which the first mask 914 is formed.

As shown in FIG. 9C, at block 806, first metal features 320 are formed in the first openings 916 such that they directly contact the seed layer 906. In some embodiments, the first metal features 320 are formed by plating (e.g., electroplating) a conductive metal (e.g., copper, aluminum, gold, nickel) into the first openings 916. In some embodiments, the first metal features 320 completely fill the first openings 916 such that an upper surface of the first metal features 320 is generally coplanar with the top surface of the first mask 914. In other embodiments, however, the first metal features 320 do not completely fill the first openings 916 and the upper surface of the first metal features 320 is recessed below the top surface of the first mask 914. In some embodiments, the skilled artisan can determine that the first metal features 320 were formed by electroplating through a resist mask, as opposed to a damascene structure filling an opening in an inorganic insulator that remains in place.

As shown in FIG. 9D, at block 808, the first mask 914 is selectively removed to expose one more portions of the seed layer 906 and to expose the sidewalls of the first metal features 320. After removing the first mask 914, the first metal features 320 can be separated from each other by gaps 326, which can extend between adjacent first metal features 320. The first mask 914 can be removed by any suitable process, such as resist stripping if the mask comprises resist.

As shown in FIG. 9E, at block 810, a second mask 918 is formed over the exposed portions of the seed layer 906 and the first metal features 320 and patterned to form second openings 920. The second mask 918 can be formed from any suitable material, such as resist, and can be patterned using any suitable patterning technique. The second openings 920 can extend through the second mask 918 such that a portion of the first metal features 320 are exposed in the second openings. The second openings 920 are smaller than the first metal features 320 such that only a portion of the first metal features 320 is exposed in the second openings 920 while the rest of the first metal features 320 are covered by the second mask 918. The size and shape of the individual second openings 920 corresponds to the planned size and shape of the corresponding second metal features (e.g., second metal features 322) that are to be formed in each of the second openings 920. The second openings 920 can have a straight profile, a V-shaped profile, or any other suitable profile and, in some embodiments, the profile can depend on the process used to pattern the second openings 920 in the second mask 918 and/or the material from which the second mask 918 is formed.

As shown in FIG. 9F, at block 812, second metal features 322 are formed in the second openings 920 such that they directly contact the first metal features 320. In some embodiments, the second metal features 322 completely fill the second openings 920 such that an upper surface of the second metal features 322 is generally coplanar with the top surface of the second mask 918. In other embodiments, however, the second metal features 322 do not completely fill the second openings 920 and the upper surface of the second metal features 322 is recessed below the top surface of the second mask 918. In some embodiments, the skilled artisan can determine that the second metal features 322 were formed by electroplating through a resist mask, as opposed to a damascene structure filling an opening in an inorganic insulator that remains in place.

As shown in FIG. 9G, at block 814, the second mask 918 is selectively removed to expose one or more portions of the seed layer 906, the first metal features 320, and the second metal features 322. After removing the second mask 918, the second metal features 322 can be separated from each other by gaps 326, which extend between adjacent second metal features 322 and between adjacent first metal features 320. The second mask 918 can be removed by any suitable process, such as resist stripping if the mask comprises resist.

As shown in FIG. 9H, at block 816, the exposed portions of the seed layer 906 and the underlying barrier layer 904 are removed to expose portions of the metallization layer 902. In some embodiments, exposing the portions of the metallization layer 902 comprises a portion of the field dielectric 908. In some embodiments, removing the exposed portion of the seed layer 906 and the underlying barrier layer 904 to expose portions of the seed layer 906 comprises removing the portions of the seed layer 906 that are not covered by the first metal features 320. In some embodiments, removing the portions of the seed layer 906 and the underlying barrier layer 904 comprises etching away the portions of the seed layer 906 and the underlying barrier layer 904 by exposing the portions the seed layer 906 and the underlying barrier layer 904 to one or more etchants. In some embodiments, etching away the exposed portions of the seed layer 906 and the underlying barrier layer 904 comprises wet etching (e.g., blanket wet etching) or dry etching the exposed portions of the seed layer 906 and the underlying barrier layer 904. In some embodiments, exposing the exposed portions of the seed layer 906 and the underlying barrier layer 904 to the etchant results in a portion of the first and second metal features 320, 322 being exposed to the etchant. In these embodiments, the etchant can also remove some of the metal from the first and second metal features 320, 322 during the etching process. Because the seed layer 906 and the barrier layer 904 are both thin relative to the first and second metal features 320, 322, the removal of the layers 904, 906 does not significantly damage the first and second metal features 320, 322.

In some embodiments, the exposed portions of the seed layer 906 and the underlying barrier layer 904 are removed in a single removal process. For example, in embodiments where the exposed portions of the seed layer 906 and the underlying barrier layer 904 are removed by exposing the exposed portions of the seed layer 906 and the underlying barrier layer 904 to etchant, the etchant can be capable of etching both the metal that forms the seed layer 906 and the conductive barrier material. In other embodiments, however, the exposed portions of the seed layer 906 and the underlying barrier layer 904 are removed in multiple processes. For example, a first etchant that is configured to selectively etch metal without etching the conductive barrier material can be used to remove the exposed portions of the seed layer 906 in a first process and then a second etchant capable of etching the conductive barrier material can be used to remove the underlying barrier layer 904. In some embodiments, at least some of the field dielectric 908 of the metallization layer 902 can also be removed during the removal of the exposed portions of the seed layer 906 and the underlying barrier layer 904. In some embodiments, at least the etch employed to remove the barrier layer 904 is selective relative to the underlying field dielectric 908 of the metallization layer 902.

As shown in FIG. 9I, at block 818, a dielectric layer 324 is formed over the first metal features 320 and the second metal features 322.

As shown in FIG. 9J, at block 820, the dielectric layer 324 and the second metal features 322 are planarized to form a surface 328 of the redistribution level 330.

In the embodiments shown and described in FIGS. 2-9J, the redistribution level 330 includes an RDL 332 and a via layer 334, where the RDL 332 includes first metal features 320 and the via layer 334 includes second metal features 322. The first and second metal features 320, 322 are electrically connected together but are formed in separate processes such that the first metal features 320 do not extend into the via layer 334 and the second metal features 322 do not extend into the RDL 332. In other embodiments, however, the redistribution level 330 can also include one or more third metal features that are formed in a single process.

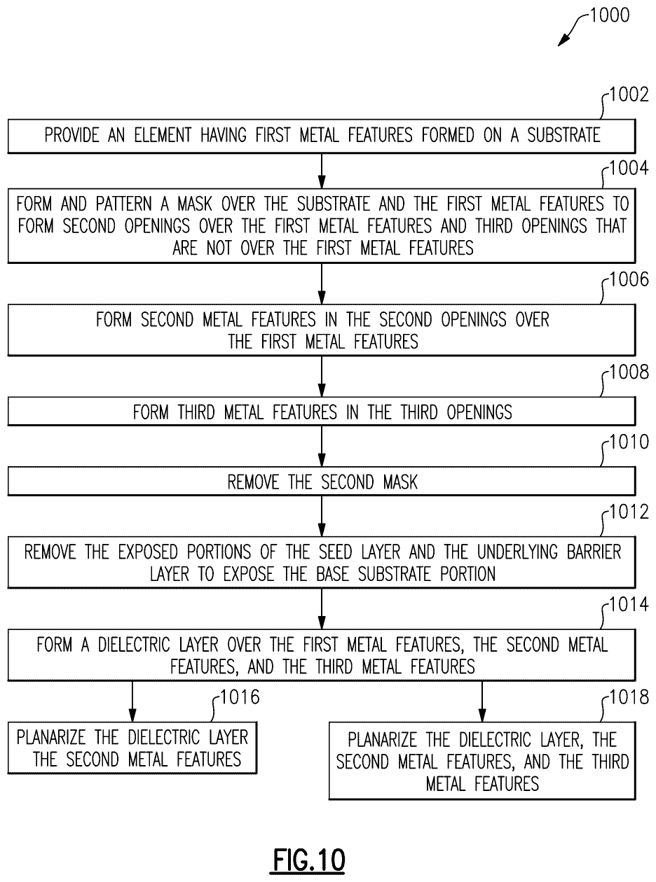

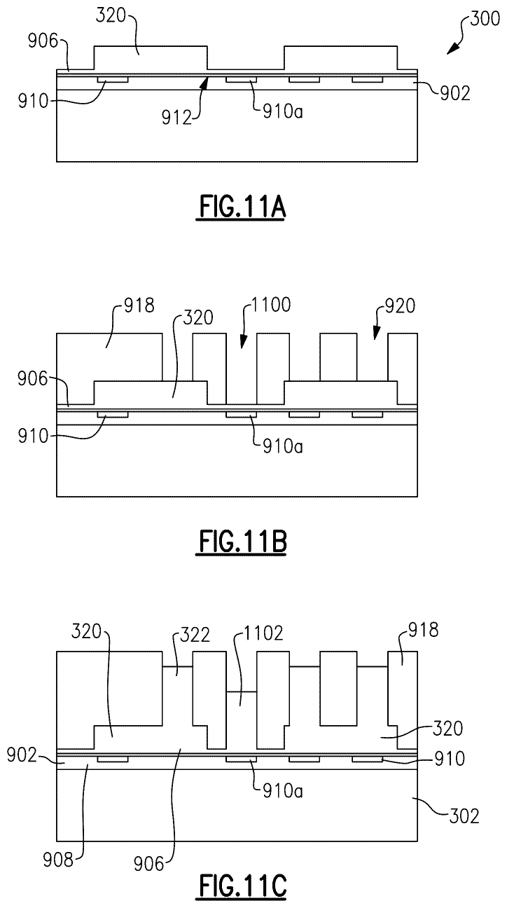

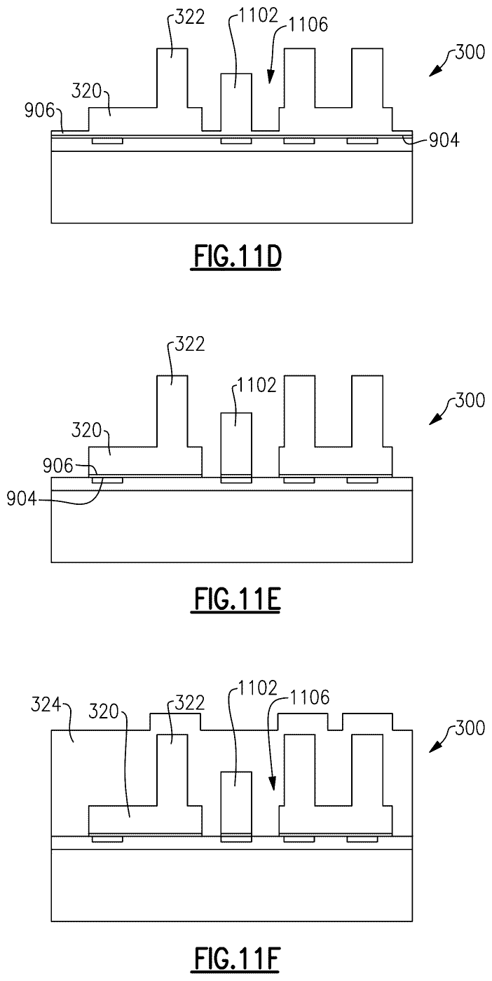

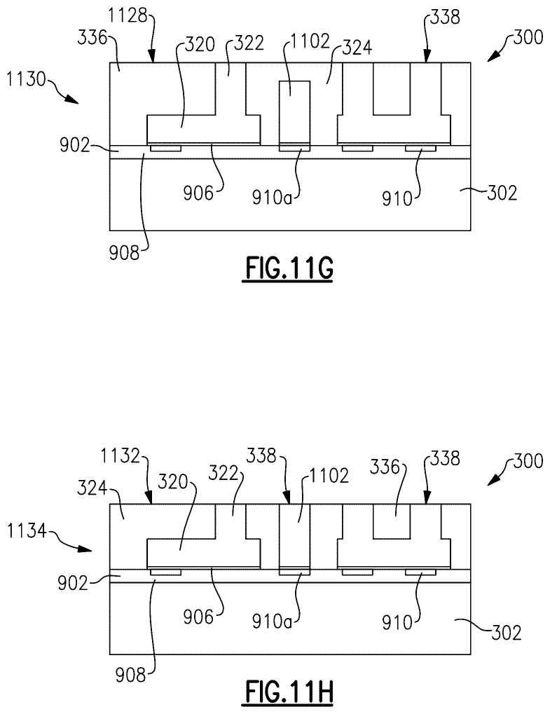

FIG. 10 is a flowchart illustrating processes 1000 for forming a build-up redistribution level on the element 300, where the redistribution level includes one or more third metal features. FIGS. 11A-11H are schematic side sectional views of the element 300 and the build-up redistribution level at various blocks of the process 1000 shown in FIG. 10.

As shown in FIG. 11A, at block 1002, an element 300 having first metal features 320 formed on substrate 302 is provided, similar to FIG. 9D. Unlike FIG. 9D, the illustrated embodiment includes one of the conductive features 910a of the metallization layer 902 positioned between and not covered by the first metal features 320.

As shown in FIG. 11B, at block 1004, a second mask 918 is formed over the seed layer 906 and the first metal features 320 and then patterned to form second openings 920 over the first metal features 320, similar to FIG. 9E, and third openings 1100 over the seed layer 906. The third openings 1100 are not formed over the first metal features 320 and are instead formed over the seed layer 906 such that the seed layer 906 is exposed in the third openings 1100 but the first metal features 320 are not exposed in the openings 1100, and can overlap with the underlying conductive features 910a. The third openings 1100 can be formed using the same process used to form the second openings 920 and can be formed at the same time with the same mask 918 as the second openings 920 are formed. The size and shape of the individual third openings 1100 corresponds to the planned size and shape of the corresponding third metal features that are to be formed in each of the openings 1100. The third openings 1100 can have a straight profile, a V-shaped profile, or any other suitable profile and, in some embodiments, the profile can depend on the process used to pattern the third openings 1100 in the second mask 918 and/or the material from which the second mask 918 is formed.

As shown in FIG. 11C, at block 1006, second metal features 322 are formed in the second openings 920 and, at block 1008, third metal features 1102 are formed in the third openings 1100. The third metal features 1102 are formed in the third openings 1100 such that they directly contact the seed layer 906 overlapping with the conductive features 910a. The third metal features 1102 comprise a conductive metal (e.g., copper, nickel, gold, and/or aluminum) and extend vertically away from the substrate 302. In some embodiments, the third metal features 1102 are formed from the same conductive metal from which the first metal features 320 and/or the second metal features 322 are formed. In some embodiments, the third metal features 1102 are formed at the same time that the second metal features 322 are formed. In some embodiments, the skilled artisan can determine that the second metal features 1102 were formed by electroplating through a resist mask, as opposed to a damascene structure filling an opening in an inorganic insulator that remains in place.

In some embodiments, including the illustrated embodiment, the third metal features 1102 are formed over one or more of the conductive features 910a that do not overlap with the first metal features 320. In these embodiments, the third metal features 1102 are formed such that they are vertically aligned with one or more of the conductive features 910a. In some embodiments, the third metal features 1102 completely fill the third openings 1100 such that an upper surface of the second metal features 1102 is generally coplanar with the top surface of the second mask 918. In other embodiments, however, the second metal features 1102 do not completely fill the third openings 1100 and the upper surface of the second metal features 1102 is recessed below the top surface of the second mask 918. In some embodiments, the third metal features 1102 are filled to the same thickness but resulting in a different height than the second metal features 322. For example, in some embodiments, the third metal features 1102 are filled to a lower height than the second metal features 322 such that the upper surface of the third metal features 1102 is lower than the upper surface of the second metal features 322. In some embodiments, the third metal features 1102 are filled such that a height of the third metal features 1102 over the seed layer 906 is about the same as the height of the second metal features 322 over the first metal features 320.

As shown in FIG. 11D, at block 1010, the second mask 918 is selectively removed to expose one or more portions of the seed layer 906, the first metal features 320, the second metal features 322, and the third metal features 1102. After removing the second mask 918, the third metal features 1102 can be separated from adjacent first metal features 320 and/or from adjacent second metal features 322 by gaps 1106. The second mask 918 can be removed by any suitable process, such as resist stripping if the mask comprises resist.

As shown in FIG. 11E, at block 1012, the exposed portions of the seed layer 906 and the underlying barrier layer 904 are removed to expose portions of the metallization layer 902.

As shown in FIG. 11F, at block 1014, a dielectric layer 324 is formed over the first metal features 320, the second metal features 322, and the third metal features 1102. In some embodiments, the dielectric layer 324 completely covers the third metal features 1102. In some embodiments, the dielectric layer 324 completely fills the gaps 1106 between adjacent ones of the first, second, or third metal features 320, 322, 1102. Like the first and second metal features 320, 322, forming the dielectric layer 324 over the already-formed third metal feature 1102 results in the dielectric material(s) of the dielectric layer 324 directly contacting the sidewalls of the third metal features 1102, which can allow for reduced annealing temperatures to be used in a subsequent annealing step due to the dielectric material(s) reacting with the metal the third metal features 1102 and forming a metal-containing ceramic material that weakly adheres to the dielectric material of the dielectric layer 324.

After depositing the dielectric layer 324 over the first, second, and third metal features 320, 322, and 1102, a planarization process is performed to form a redistribution level 1130 or 1134. The redistribution level 1130 or 1134 can be generally similar to the redistribution level 330 shown and described above in connection with FIGS. 2-9J except for the presence of the third metal features 1102. In some embodiments, only the dielectric layer 324 and the second metal features 322 are planarized during the planarization process. In other embodiments, however, the dielectric layer 324, the second metal features 322, and one or more of the third metal features 1102 are planarized during the planarization process. In embodiments where only the dielectric layer 324 and the second metal features 322 are planarized, the process 1000 proceeds to block 1016. In embodiments where the third metal features 1102 are also planarized, the process 1000 proceeds to block 1018.

As shown in FIG. 11G, at block 1016, the dielectric layer 324 and the second metal features 322 are planarized to form a surface 1128 of the redistribution level 1130. The surface 1128 can be generally similar to the surface 328 shown and described above in connection with FIGS. 2-9J. The third metal features 1102 can be formed such that the upper surface of the third metal features 1102 is below the upper surface of the second metal features 322. Accordingly, planarizing the dielectric layer 324 and the second metal features 322 comprises planarizing the dielectric layer 324 and the second metal features 322 until the second metal features 322 are exposed but without exposing the third metal features 1102. With this arrangement, the second metal features 322 and the dielectric layer 324 are exposed at the surface 1128 but the third metal features 1102 remain covered by the dielectric layer 324 and are not exposed at the surface 1128. In embodiments where the surface 1128 comprises a bonding surface, the dielectric field region 336 is formed by the dielectric layer 324 and the bond pads 338 are formed from the second metal features 322. In these embodiments, the third metal features 1102 form buried metal features (e.g., buried metal lines) that can be used to facilitate electrical communication between active circuitry within the substrate 302 but do not form bond pads 338 for the bonding surface.

As shown in FIG. 11H, at block 1018, the dielectric layer 324, the second metal features 322, and the third metal features 1102 are planarized to form a surface 1132 of the redistribution level 1134. In these embodiments, the dielectric layer 324 and the second metal features 322 are planarized until the third metal features 1102 are exposed. With this arrangement, the dielectric layer 324, the second metal features 322, and the third metal features 1102 are exposed at the surface 1128. In embodiments where the surface 1128 comprises a bonding surface, the dielectric field region 336 is formed by the dielectric layer 324 and the bond pads 338 are formed from the second metal features 322 and third metal features 1102. In some embodiments, all of the third metal features 1102 are exposed at the surface 1128. In other embodiments, however, one or more of the third metal features 1102 can remain covered by the dielectric layer 324 after the planarization process and form a buried metal feature that is not exposed at the surface 1128.

After forming the redistribution level 1130 or 1134, the surface 1128 or 1132 can prepared for hybrid bonding and then the redistribution level 1130 or 1134 is hybrid bonded to another element (e.g., second element 500 shown and described above in connection with FIG. 7B). In some embodiments, preparing the surface 1128 or 1132 for hybrid bonding comprises polishing, activating, rinsing, drying, and/or terminating the surface. In some embodiments, only the second element 500 is activated and/or terminated. In embodiments where the third metal features 1102 are exposed at the surface 1132, preparing the surface 1132 for hybrid bonding comprises preparing the third metal features 1102 for hybrid bonding. After hybrid bonding the redistribution level 1130 or 1134 to the second element, the bonded structure can undergo additional such as singulating the bonded structure, thinning the bonded structure (either before or after being singulated and/or bonded to another element or after), etching the backsides of one or both of the bonded elements, and/or bonding one or more other elements (e.g., dies, substrates, wafers, etc.) to the backside(s) of one or both of the elements. In some embodiments, the substrate 302 can be removed from the redistribution level 1130 or 1134 after hybrid bonding the redistribution level 1130 or 1134 to the second element.

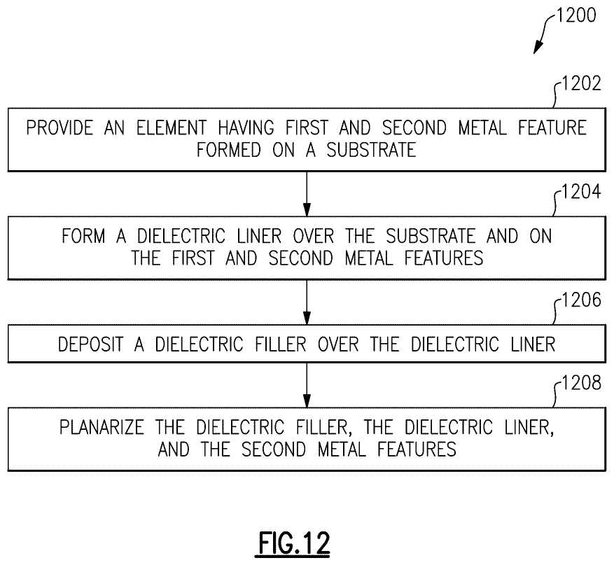

In the embodiments shown and described in FIGS. 2-11H, the dielectric layer 324 is depicted as being formed directly on the first and second metal features 320, 322 such that the dielectric layer 324 directly contacts the first and second metal features 320, 322. In other embodiments, however, a dielectric liner can be formed on the first and second metal features 320, 322 and then a dielectric layer is formed over the dielectric liner. FIG. 12 is a flowchart illustrating a process 1200 for forming a build-up redistribution level that includes a dielectric liner formed directly on the first and second metal features 320, 322. FIG. 13A-13C are schematic side sectional views of the element 300 and the redistribution level at various blocks of the process 1200 shown in FIG. 12. It will be appreciated that the process is equally applicable to filling gaps between first and second metal features 720, 722 of FIG. 7B

As shown in FIG. 13A, at block 1202, element 300 having first and second metal features 320, 322 formed on substrate 302 is provided.

As shown in FIG. 13B, at block 1204, dielectric liner 1300 is formed over the substrate 302 and the first and second metal features 320, 322. The dielectric liner 1300 is formed such that it directly contacts the sidewalls of the first and second metal features 320, 322. The dielectric liner 1300 can be formed conformally and can completely cover the first metal features 320 and the second metal features 322. The dielectric liner 1300 has a thickness of 10 nm to 100 nm. For example, in some embodiments, the dielectric liner has a thickness of 10 nm to 20 nm, 20 nm to 40 nm, 40 nm to 60 nm, 60 nm to 80 nm, 80 nm to 100 nm, or a value in a range defined by any of these values. The dielectric liner 1300 may only partially fill the gaps 326 between adjacent first and second metal features 322 such that, after forming the dielectric liner 1300 over the first and second metal features 320, 322, the gaps 326 are still present. In some embodiments, the dielectric liner 1300 comprises an inorganic dielectric material, such as silicon nitride (Si₃N₄), silicon oxynitride (SiNₓO_{y}), or silicon carbon nitride (SiCN). In some embodiments, the inorganic dielectric material can also function as a barrier material. Forming the dielectric liner 1300 over the already-formed first and second metal features 320, 322 results in the dielectric material of the dielectric liner 1300 directly contacts the sidewalls of the first and second metal features 320, 322, which can allow for reduced annealing temperatures to be used in a subsequent annealing step.

As shown in FIG. 13C, at block 1206, dielectric layer 1324 is formed over the dielectric liner 1300. The dielectric layer 1324, which can be generally similar to dielectric layer 324, is formed over the dielectric liner 1300 such that it completely covers the dielectric liner 1300. The dielectric layer 1324 can be formed such that it completely fills the remainder of the gaps 326. In some embodiments, the dielectric layer 1324 comprises a single dielectric material. In other embodiments, the dielectric layer 1324 comprises multiple dielectric materials layered together. In some embodiments, the dielectric layer 1324 comprises an inorganic dielectric material, such as a silicon oxide-based material. For example, in some embodiments, the dielectric layer 1324 comprises silicon oxide (SiO₂), silicon oxynitride, silicon oxycarbide, or doped silicon oxide, such as F-doped SiO₂, borosilicate glass (BSG), or borophosphosilicate glass (BPSG).

As shown in FIG. 13D, at block 1208, the dielectric layer 1324, the dielectric liner 1300, and the second metal features 322 are planarized to form a surface 1328. After planarizing the dielectric layer 1324, the dielectric liner 1300, and the second metal features 322, the dielectric layer 1324, the dielectric liner 1300, and the second metal features 322 are exposed at the surface 1328. In some embodiments, planarizing the dielectric layer 1324 and the dielectric liner 1300 comprises completely removing the portions of the dielectric layer 1324 and the dielectric liner 1300 formed above the second metal features 322 to expose the second metal features 322. In some embodiments, planarizing the dielectric layer 1324 also comprises removing some of the dielectric layer 1324 that is formed in the gaps 326 between adjacent second metal features 322. In some embodiments, planarizing the second metal features 322 comprises removing at least some of the metal that forms the second metal features 322. In some embodiments, after planarizing the dielectric layer 1324 and the dielectric liner 1300, the second metal features 322 can be recessed below the dielectric layer 1324 and the dielectric liner 1300 at the surface 1328.

The dielectric layer 1324, the dielectric liner 1300, and the second metal features 322 can be planarized to form the redistribution level 1330. The redistribution level 1330 can be generally similar to the redistribution level 330 shown and described above in connection with FIGS. 2-11H except for the presence of the dielectric liner 1300. The dielectric layer 1324, the dielectric liner 1300, and the second metal features 322 can be planarized using any suitable planarization process, such as a CMP process. In some embodiments, planarizing the dielectric layer 1324, the dielectric liner 1300, and the second metal feature 322 can be performed with a single polishing pad and a single slurry chemistry (e.g., a “barrier slurry”). After performing the CMP process using the single polishing pad and the single slurry chemistry, the top surface of the second metal features 322 can be recessed below the top surface of the dielectric layer 1324.

In some embodiments, the surface 1328 comprises a bonding surface. In these embodiments, the bonding surface can include a dielectric field region 1306 and bond pads 1308, where the dielectric field region 1306 includes the dielectric layer 1324 and the dielectric liner 1300 and the bond pads 1308 are formed from the second metal features 322. In some embodiments, the bond pads 1308 are recessed below the dielectric field region 1306.

### Additional Examples

According to one aspect, a method is provided forming a microelectronic component. The method includes providing a substrate having a first surface, forming a first metal feature on the first surface, forming a second metal feature on the first metal feature, forming a dielectric layer over the substrate such that the dielectric layer directly contacts sidewalls of the first and second metal features, and planarizing the dielectric layer to form a second surface for hybrid bonding. The second metal feature is exposed at the second surface.

In some embodiments, the first metal feature includes a routing line. In some embodiments, at least a portion of the routing line extends in a direction parallel to the first surface. In some embodiments, the second metal feature includes a via. In some embodiments, the second metal feature includes a bond pad. In some embodiments, the substrate includes a microelectronic element having a metallization layer that includes a field dielectric and a conductive feature embedded in the field dielectric, where the first surface includes the field dielectric and the conductive feature. In some embodiments, forming the first metal feature over the substrate includes forming the first metal feature in electrical contact with the conductive feature. In some embodiments, the second metal feature is not vertically aligned with the conductive feature. In some embodiments, the method includes forming a third metal feature on the first surface before forming the dielectric layer, where forming the dielectric layer over the substrate includes forming the dielectric layer such that it directly contacts sidewalls of the third metal feature. In some embodiments, before forming the dielectric layer, the third metal feature is not electrically connected to the first metal feature or the second metal feature. In some embodiments, an upper surface of the third metal feature is not covered by the dielectric layer. In some embodiments, after planarizing the dielectric layer, an upper surface of the third metal feature is covered by the dielectric layer. In some embodiments, the third metal feature is spaced apart from the first metal feature by a gap and forming the dielectric layer over the substrate includes forming the dielectric layer over the substrate such that it at least partially fills the gap. In some embodiments, the method further includes preparing the second surface for hybrid bonding. In some embodiments, the substrate includes a base substrate portion and a first redistribution level, the microelectronic component includes a second redistribution level that includes the first metal feature, the second metal feature, the dielectric layer and the second surface, the first redistribution level is formed on the base substrate portion, and the first redistribution level includes the first surface. In some embodiments, the method further includes forming the first redistribution level on the base substrate portion before providing the substrate.

According to another aspect, a microelectronic component is provided. The microelectronic component includes a substrate having a surface and a redistribution level formed on the surface. The redistribution level includes a first metal feature on the surface a second metal feature on the first metal feature, and a dielectric material, where the dielectric material directly contacts sidewalls of the first and second metal features and the redistribution level does not include a barrier layer between the sidewalls of the first and second features and the dielectric material or between the first and second metal features. The second metal feature and the dielectric material form part of a hybrid bonding surface.

In some embodiments, the first metal feature includes a routing line. In some embodiments, at least a portion of the routing line extends in a direction parallel to the surface of the substrate. In some embodiments, the second metal feature includes a via. In some embodiments, the second metal feature includes a bond pad. In some embodiments, the substrate includes a microelectronic element having a metallization layer that includes a field dielectric and a conductive feature embedded in the field dielectric, where the surface includes the field dielectric and the conductive feature. In some embodiments, the first metal feature is on the conductive feature. In some embodiments, the second metal feature is not vertically aligned with the conductive feature. In some embodiments, the redistribution level includes a first redistribution level, the substrate includes a base substrate portion and a second redistribution level, and the second redistribution level includes the surface. In some embodiments, the second redistribution level is positioned between the base substrate portion and the first redistribution level.

According to another aspect, a method of forming a microelectronic component is provided. The method includes providing a substrate having a first surface, forming a plurality of routing lines on the first surface, forming a plurality of vias on the routing lines, forming a dielectric layer over the substrate and on the routing lines and the vias such that the dielectric layer is positioned between adjacent ones of the routing lines and between adjacent ones of the vias, and planarizing the dielectric layer to form a second surface for hybrid bonding. Top portions of the vias are exposed at the second surface.

In some embodiments, forming the dielectric layer on the routing lines includes forming the dielectric layer such that the dielectric layer covers the routing lines. In some embodiments, each of the routing lines includes sidewalls, where forming the dielectric layer on the routing lines comprise forming the routing lines such that dielectric layer directly contacts the sidewalls. In some embodiments, the top portions of the vias comprise bond pads.

According to another aspect, a microelectronic component is provided. The microelectronic component includes a substrate having a surface and a redistribution level formed on the surface. The redistribution level includes a plurality of routing lines on first surface, a plurality of vias on the plurality of routing lines, and a dielectric material. Each of the vias is formed directly on one of the routing lines and the redistribution level does not include a barrier layer between sidewalls of each of the routing lines and the dielectric material or between sidewalls of each of the vias and the dielectric material. The vias and the dielectric material form part of a hybrid bonding surface.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A method of forming a microelectronic component, the method comprising:
providing a substrate having a first surface;
forming a first metal feature on the first surface;
forming a second metal feature on the first metal feature;
after forming the second metal feature on the first metal, forming a dielectric layer over the substrate such that the dielectric layer directly contacts sidewalls of the first and second metal features; and
planarizing the dielectric layer to form a second surface for hybrid bonding, wherein the second metal feature is exposed at the second surface.

2. The method of claim 1, wherein the first metal feature comprises a routing line and wherein at least a portion of the routing line extends in a direction parallel to the first surface.

3. (canceled)

4. The method of claim 1, wherein the second metal feature comprises a via.

5. The method of claim 1, wherein the second metal feature comprises a bond pad.

6. The method of claim 1, wherein the substrate comprises a microelectronic element having a metallization layer that comprises a field dielectric and a conductive feature embedded in the field dielectric, wherein the first surface includes the field dielectric and the conductive feature, and wherein forming the first metal feature over the substrate comprises forming the first metal feature in electrical contact with the conductive feature.

7. (canceled)

8. The method of Claim 6, wherein the second metal feature is not vertically aligned with the conductive feature.

9. The method of claim 1, further comprising:
before forming the dielectric layer, forming a third metal feature on the first surface, wherein the third metal feature is spaced apart from the first metal feature by a gap, wherein forming the dielectric layer over the substrate comprises forming the dielectric layer such that it directly contacts sidewalls of the third metal feature and at least partially fills the gap.

10. (canceled)

11. The method of claim 9, wherein an upper surface of the third metal feature is not covered by the dielectric layer.

12. The method of claim 9, wherein after planarizing the dielectric layer, an upper surface of the third metal feature is covered by the dielectric layer.

13. (canceled)

14. The method of claim 1, further comprising:
preparing the second surface for hybrid bonding.

15. The method of claim 1, wherein the substrate comprises a base substrate portion and a first redistribution level, wherein the microelectronic component comprises a second redistribution level that comprises the first metal feature, the second metal feature, the dielectric layer and the second surface, wherein the first redistribution level is formed on the base substrate portion, and wherein the first redistribution level comprises the first surface.

16. (canceled)

17. A microelectronic component, comprising:
a substrate having a surface; and
a redistribution level formed on the surface, wherein the redistribution level comprises:
a first metal feature on the surface;
a second metal feature on the first metal feature; and
a dielectric material, wherein the dielectric material directly contacts sidewalls of the first and second metal features, and wherein the redistribution level does not include a barrier layer between the sidewalls of the first and second features and the dielectric material or between the first and second metal features, wherein the second metal feature and the dielectric material form part of a hybrid bonding surface.

18. The microelectronic component of claim 17, wherein the first metal feature comprises a routing line and wherein at least a portion of the routing line extends in a direction parallel to the surface of the substrate.

19. (canceled)

20. The microelectronic component of claim 17, wherein the second metal feature comprises a via.

21. The microelectronic component of claim 20, wherein the second metal feature comprises a bond pad.

22. The microelectronic component of claim 17, wherein the substrate comprises a microelectronic element having a metallization layer that comprises a field dielectric and a conductive feature embedded in the field dielectric, wherein the surface includes the field dielectric and the conductive feature, and wherein the first metal features is on the conductive feature.

23. (canceled)

24. (canceled)

25. The microelectronic component of claim 17, wherein the redistribution level comprises a first redistribution level, wherein the substrate comprises a base substrate portion and a second redistribution level, and wherein the second redistribution level comprises the surface.

26. (canceled)

27. A method of forming a microelectronic component, the method comprising:
providing a substrate having a first surface;
forming a plurality of routing lines on the first surface;
forming a plurality of vias on the routing lines;
forming a dielectric layer over the substrate and on the routing lines and the vias such that the dielectric layer is positioned between adjacent ones of the routing lines and between adjacent ones of the vias; and
planarizing the dielectric layer to form a second surface for hybrid bonding, wherein top portions of the vias are exposed at the second surface.

28. The method of claim 27, wherein forming the dielectric layer on the routing lines comprises forming the dielectric layer such that the dielectric layer covers the routing lines.

29. The method of claim 28, wherein each of the routing lines comprises sidewalls and wherein forming the dielectric layer on the routing lines comprise forming the routing lines such that dielectric layer directly contacts the sidewalls.

30. The method of claim 27, wherein the top portions of the vias comprise bond pads.

31. (canceled)

32. The microelectronic component of claim 17, wherein the first and second metal features comprise copper.
